(19) United States
(12) Patent Application Publication
(10) Pub. No.: US 2014/0287599 A1
(43) Pub. Date: Sep. 25, 2014

(54) SUBSTRATE PROCESSING APPARATUS, PROCESS CONTAINER, AND METHOD OF MANUFACTURING SEMICONDUCTOR DEVICE

(71) Applicant: HITACHI KOKUSAI ELECTRIC INC., Tokyo (JP)

(72) Inventors: Tsukasa KAMAKURA, Toyama-shi (JP); Yoshiro HIROSE, Toyama-shi (JP)

(73) Assignee: HITACHI KOKUSAI ELECTRIC INC., Tokyo (JP)

(21) Appl. No.: 14/204,380

(22) Filed: Mar. 11, 2014

(30) Foreign Application Priority Data
Mar. 22, 2013 (JP) 2013-060341

(51) Int. Cl. H01L 21/268; F26B 3/28

(52) U.S. Cl. CPC H01L 21/268; F26B 3/283
USPC 438/795; 34/245

(57) ABSTRACT

Provided are a substrate processing apparatus, a process container and a method of manufacturing a semiconductor device capable of improving the quality of a thin film by stabilizing conditions of heating a substrate when the thin film is formed on the substrate heated using a heating unit installed outside the process container. The substrate processing apparatus includes a process container in which processing to a substrate is performed; a heating unit disposed outside the process container and configured to emit a radiant heat so as to heat the substrate in the process container; and a source gas supply system configured to supply a source gas into the process container, wherein the process container includes a heat absorbing layer disposed on at least a portion of an outer wall of the process container and configured to absorb the radiant heat and cause a saturation of absorption of the radiant heat.

### CROSS-REFERENCE TO RELATED PATENT APPLICATION

This U.S. non-provisional patent application claims priority under 35 U.S.C. §119 of Japanese Patent Application No. 2013-060341 filed on Mar. 22, 2013 in the Japanese Patent Office, the entire contents of which are hereby incorporated by reference.

### BACKGROUND OF THE INVENTION

1. Field of the Invention

The present invention relates to a substrate processing apparatus for forming a thin film on a substrate, a process container, and a method of manufacturing a semiconductor device.

2. Description of the Related Art

As a process included in a process of manufacturing a semiconductor device, a substrate processing process may be performed to form a thin film on a heated substrate in a process container by supplying a source gas onto the heated substrate.

### SUMMARY OF THE INVENTION

When a substrate is heated using a heating unit installed outside a process container, the substrate is heated mainly using three heating paths which will be described below. That is, the substrate is heated when radiant heat radiated from the heating unit (hereinafter referred to also as ‘primary radiant heat’) passes through a process container and is applied onto a substrate, when radiant heat is emitted from the process container when the process container is heated (hereinafter referred to also as ‘secondary radiant heat’) and applied onto the substrate, and when the substrate comes in contact with a heat-temperature atmosphere in the process container.

Here, when the substrate processing process described above is performed, a thin film is formed not only on the substrate but also on an inner wall of the process container (hereinafter, the thin film formed on the inner wall of the process container will be referred to also as a ‘deposited film’). The deposited film acts to absorb or reflect at least a part of the primary radiant heat radiated from the heating unit. Thus, when the deposited film changes in thickness, for example, by repeatedly performing the substrate processing process, the amount (intensity) of the primary radiant heat applied onto the substrate, i.e., conditions of heating the substrate, may gradually change, thereby influencing the quality of a film to be formed. Also, when, for example, a cleaning process is performed to remove the deposited film formed in the process container, the amount of the primary radiant heat applied onto the substrate changes to a large degree before and after the cleaning process is performed, thereby greatly influencing the quality of a film to be formed.

It is a main object of the present invention to improve the quality of a thin film by stabilizing conditions of heating a substrate when the thin film is formed on the substrate heated using a heating unit installed outside a process container.

According to one aspect of the present invention, there is provided a substrate processing apparatus including:

a process container in which processing to a substrate is performed;

a heating unit disposed outside the process container and configured to emit a first radiant heat so as to heat the substrate in the process container; and

a source gas supply system configured to supply a source gas into the process container,

wherein the process container includes a heat absorbing layer disposed on at least a portion of an outer wall of the process container and configured to absorb the first radiant heat and cause a saturation of an absorption of the first radiant heat.

According to another aspect of the present invention, there is provided a process container in which processing to a substrate is performed, the process container including a heat absorbing layer disposed on at least a portion of an outer wall thereof and configured to absorb radiant heat and cause a saturation of an absorption of the radiant heat,

wherein the process container is configured such that the substrate in the process container is heated by the radiant heat emitted by an external heating unit and a source gas is supplied into the process container by a source gas supply system.

According to another aspect of the present invention, there is provided a method of manufacturing a semiconductor device, the method including:

(a) loading a substrate into a process container including a heat absorbing layer disposed on at least a portion of an outer wall thereof and configured to absorb radiant heat emitted by a heating unit and cause a saturation of an absorption of the radiant heat;

(b) forming a thin film on the substrate by heating the substrate by emitting the radiant heat from the heating unit to the substrate in the process container and supplying a source gas to the substrate in the process container; and

(c) unloading the substrate from the process container after the step (b) is performed.

### BRIEF DESCRIPTION OF THE DRAWINGS

FIG. 1 is a schematic configuration diagram of a longitudinal process furnace of a substrate processing apparatus according to an exemplary embodiment of the present invention, in which a longitudinal cross-sectional view of a portion of the process furnace is illustrated.

FIG. 2 is a schematic configuration diagram of a longitudinal process furnace of a substrate processing apparatus according to an exemplary embodiment of the present invention, in which a cross-sectional view of the process furnace taken along line A-A of FIG. 1 is illustrated.

FIG. 3 is a schematic configuration diagram of a controller of a substrate processing apparatus according to an exemplary embodiment of the present invention, in which a block diagram of a control system of the controller is illustrated.

FIGS. 4A and 4B are a flowchart of a substrate processing process, a cleaning process and a pre-coating process according to an exemplary embodiment of the present invention.

FIG. 5 is a timing chart illustrating gas supply timing in a substrate processing process according to an exemplary embodiment of the present invention.

FIG. 6 is a graph illustrating a relationship between the thickness of a heat absorbing layer formed on an outer wall of a process container and the amount (intensity) of primary radiant heat applied onto a substrate.

### DETAILED DESCRIPTION OF THE PREFERRED EMBODIMENTS

### One Embodiment of the Present Invention

One embodiment of the present invention will be now described with reference to the accompanying drawings below.

(1) Structure of Substrate Processing Apparatus

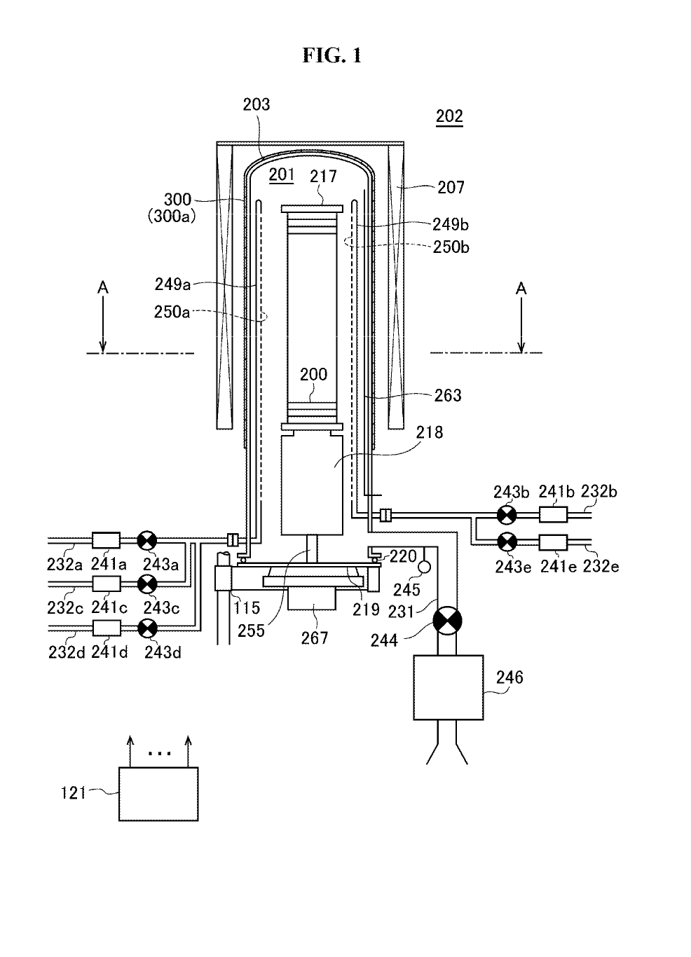

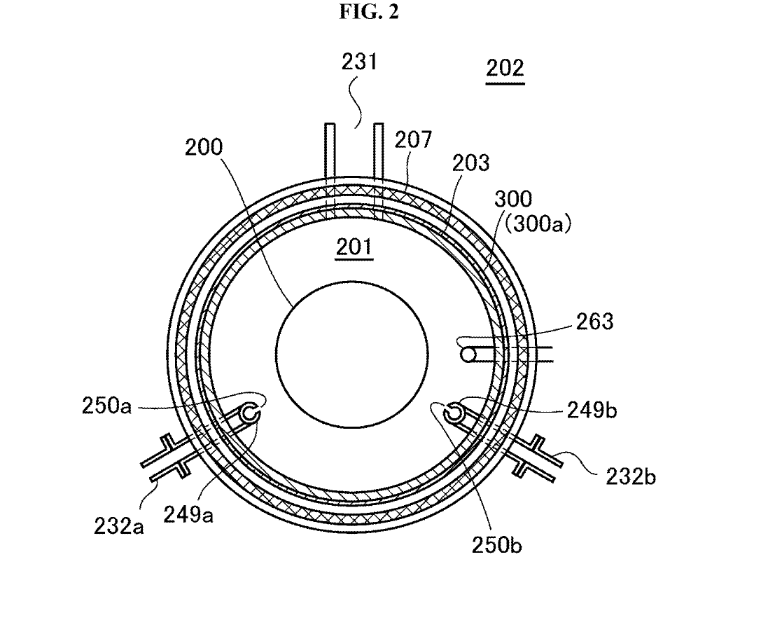

FIG. 1 is a schematic configuration diagram of a longitudinal process furnace 202 of a substrate processing apparatus according to an exemplary embodiment of the present invention, in which a longitudinal cross-sectional view of a portion of the process furnace 202 is illustrated. FIG. 2 is a schematic configuration diagram of the longitudinal process furnace 202 of the substrate processing apparatus according to an exemplary embodiment of the present invention, in which a cross-sectional view of the process furnace taken along line A-A of FIG. 1 is illustrated.

As illustrated in FIG. 1, the process furnace 202 includes a heater 207 serving as a heating unit. The heater 207 has a cylindrical shape and is vertically installed by being supported by a heater base (not shown) serving as a retaining plate. Also, the heater 207 acts as an activating mechanism (excitation unit) that activates a gas with heat as will be described below.

In the heater 207, a reaction tube 203 forming a reaction container (process container) in a concentric shape with the heater 207 is provided. The reaction tube 203 is formed of a heat-resistant and permeable material capable of allowing radiant heat (primary radiant heat) radiated from the heater 207 to pass therethrough, e.g., quartz (SiO₂) or silicon carbide (SiC), and has a cylindrical shape, an upper end of which is closed and a lower end of which is open. A process chamber 201 is formed in a hollow tubular portion of the reaction tube 203, and configured to accommodate wafers 200 serving as substrates such that the wafers 200 are vertically arranged in a horizontal posture and in multiple stages using a boat 217 which will be described below.

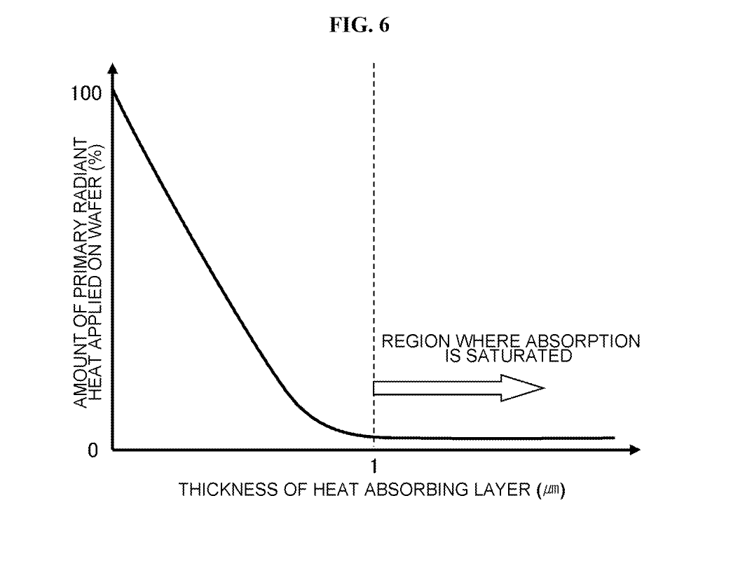

A heat absorbing layer 300 serving as a buffer layer is formed (coated) on at least portions of an outer wall of the reaction tube 203, and particularly, side and ceiling portions of the outer wall of the reaction tube 203 that are opposite to (that face) the heater 207. That is, the heat absorbing layer 300 is formed on portions of the outer wall of the reaction tube 203 to which radiant heat radiated from the heater 207 is delivered. A thickness of the heat absorbing layer 300 is set such that absorption of the amount (intensity) of the primary radiant heat (which is radiated from the heater 207, passes through the heat absorbing layer 300 and the reaction tube 203, and is then applied onto the wafers 200) is saturated, i.e., the amount (intensity) of the primary radiant heat does not increase any more even when the heat absorbing layer 300 becomes thicker. FIG. 6 is a graph illustrating a relationship between the thickness of the heat absorbing layer 300 formed on the outer wall of the process container and the amount (intensity) of the primary radiant heat applied onto the wafers 200. The wafers 200 are heated mainly using two heating paths in a substrate processing process (which will be described below) by saturating the absorption of the primary radiant heat radiated from the heater 207 by the heat absorbing layer 300. That is, the wafers 200 are heated mainly by: radiant heat (secondary radiant heat) emitted to the wafers 200 from the reaction tube 203 heated by the primary radiant heat when the absorption of the primary radiant heat by the heat absorbing layer 300 is saturated; and transferred heat transferred to the wafer 200 from an atmosphere in the reaction tube 203 when the wafer 200 is exposed to the atmosphere.

Also, the heat absorbing layer 300 may be formed of a material having the same optical features as (i.e., optically equivalent to) a material constituting a deposited film on an inner wall of the reaction tube 203 (or a material constituting a thin film on the wafers 200) in the substrate processing process which will be described below. For example, the heat absorbing layer 300 may be formed of a material having an absorption coefficient equal to that of the material constituting the deposited film described above (or the material constituting the thin film formed on the wafers 200) with respect to the primary radiant heat radiated from the heater 20. Also, the reflectivity of the material constituting the heat absorbing layer 300 with respect to the primary radiant heat may be equal to that of the material constituting the deposited film (or the material constituting the thin film formed on the wafers 200) with respect to the primary radiant heat.

Also, when an amorphous silicon film or a polysilicon film is formed on the wafers 200 as in the substrate processing process which will be described below, a deposited film that is mainly formed of amorphous silicon or polysilicon is also formed on the inner wall of the reaction tube 203. In this case, the heat absorbing layer 300 may be formed, for example, of amorphous silicon or polysilicon. An absorption coefficient of amorphous silicon with respect to primary radiant heat is higher than that of polysilicon with respect to primary radiant heat. When the heat absorbing layer 300 is formed of such a material, a thickness of the heat absorbing layer 300 may be set to, for example, 0.8 μm or more, and preferably 1 μm or more so that absorption of the primary radiant heat from the heater 207 may be saturated by the heat absorbing layer 300.

In the process chamber 201, a first nozzle 249a and a second nozzle 249b are installed to pass through lower sidewalls of the reaction tube 203. A first gas supply pipe 232a and a second gas supply pipe 232b are connected to the first nozzle 249a and the second nozzle 249b, respectively. A third gas supply pipe 232c is also connected to the first gas supply pipe 232a. As described above, the reaction tube 203 is configured to install the two nozzles 249a and 249b and the three gas supply pipes 232a to 232c therein and to supply a plurality of gases (here, three types of gases) into the process chamber 201.

Also, a manifold formed of a metal may be installed below the reaction tube 203 to support the reaction tube 203, and the first and second nozzles 249a and 249b may be installed to pass through sidewalls of the manifold. In this case, an exhaust pipe 231 which will be described below may be installed in the manifold formed of a metal. Alternatively, the exhaust pipe 231 may be installed below the reaction tube 203 rather than in the manifold formed of a metal. As described above, a furnace port portion of the process furnace 202 may be formed of a metal and the first and second nozzles 249a and 249b may be installed at the furnace port portion formed of a metal.

A mass flow controller (MFC) 241a which is a flow rate control device (flow rate control unit) and a valve 243a which is an opening/closing valve are sequentially installed at the first gas supply pipe 232a in an upstream direction. The third gas supply pipe 232c is connected to the first gas supply pipe 232a at a downstream side of the valve 243a. An MFC 241c which is a flow rate control device (flow rate control unit) and a valve 243c which is an opening/closing valve are sequentially installed at the third gas supply pipe 232c in the upstream direction. A first inert gas supply pipe 232d is connected to the second gas supply pipe 232b at a downstream side of a point on the second gas supply pipe 232b connected to the third gas supply pipe 232c. An MFC 241d which is a flow rate control device (flow rate control unit) and a valve 243d which is an opening/closing valve are sequentially installed at the first inert gas supply pipe 232d in the upstream direction. The first nozzle 249a described above is connected to a front end portion of the first gas supply pipe 232a. The first nozzle 249a is installed in an arc-shaped space between inner walls of the reaction tube 203 and the wafers 200 to move upward from lower inner walls of the reaction tube 203 in a direction in which the wafers 200 are stacked. In other words, the first nozzle 249a is installed along a wafer arrangement region in which the wafers 200 are arranged, in a region that horizontally surrounds the wafer arrangement region at sides of the wafer arrangement region. The first nozzle 249a is configured as an L-shaped long nozzle, and includes a horizontal portion passing through lower sidewalls of the reaction tube 203 and a vertical portion vertically moving at least from one end of the wafer arrangement region toward the other end thereof. A plurality of gas supply holes 250a are formed in a side surface of the first nozzle 249a to supply a gas. The gas supply holes 250a open toward a center of the reaction tube 203 to supply a gas toward the wafers 200. The gas supply holes 250a are formed from a lower portion of the reaction tube 203 to an upper portion thereof and each have the same opening area at the same opening pitch.

A first gas supply system mainly includes the first gas supply pipe 232a, the MFC 241a, and the valve 243a. The first gas supply system may further include the first nozzle 249a. A third gas supply system mainly includes the third gas supply pipe 232c, the MFC 241c, and the valve 243c. The third gas supply system may further include the first nozzle 249a connected to the first gas supply pipe 232a at a downstream side of a point on the first gas supply pipe 232a connected to the third gas supply pipe 232c. A first inert gas supply system mainly includes the first inert gas supply pipe 232d, the MFC 241d, and the valve 243d. The first inert gas supply system may also function as a purge gas supply system.

An MFC 241b which is a flow rate control device (flow rate controller) and a valve 243b which is an opening/closing valve are sequentially installed at the second gas supply pipe 232b in the upstream direction. A second inert gas supply pipe 232e is connected to the second gas supply pipe 232b at a downstream side of the valve 243b. An MFC 241e which is a flow rate control device (flow rate controller) and a valve 243e which is an opening/closing valve are sequentially installed at the second inert gas supply pipe 232e in the upstream direction. The second nozzle 249b described above is connected to a front end portion of the second gas supply pipe 232b. The second nozzle 249b is installed in the arc-shaped space between the inner walls of the reaction tube 203 and the wafers 200 to move upward from the lower inner walls of the reaction tube 203 in the direction in which the wafers 200 are stacked. In other words, the second nozzle 249b is installed along the wafer arrangement region in which the wafers 200 are arranged, in the region that horizontally surrounds the wafer arrangement region at the sides of the wafer arrangement region. The second nozzle 249b is configured as an L-shaped long nozzle, and includes a horizontal portion passing through the lower sidewalls of the reaction tube 203 and a vertical portion vertically moving at least from one end of the wafer arrangement region toward the other end thereof. A plurality of gas supply holes 250b are formed in a side surface of the second nozzle 249b to supply a gas. The gas supply holes 250b open toward the center of the reaction tube 203 to supply a gas toward the wafers 200. The gas supply holes 250b are formed from the lower portion of the reaction tube 203 to the upper portion thereof and each have the same opening area at the same opening pitch.

A second gas supply system mainly includes the second gas supply pipe 232b, the MFC 241b, and the valve 243b. The second gas supply system may further include the second nozzle 249b. A second inert gas supply system mainly includes the second inert gas supply pipe 232e, the MFC 241e, and the valve 243e. The second inert gas supply system may also function as a purge gas supply system.

As described above, in the present embodiment, a gas is transferred via the first and second nozzles 249a and 249b arranged in the arc-shaped space that is a vertically long space defined with the inner walls of the reaction tube 203 and end portions of the wafers 200, a gas is first emitted into the reaction tube 203 near the wafers 200 from the gas supply holes 250a open in the first nozzle 249a and the gas supply holes 250b open in the second nozzle 249b, and a gas flows mainly in the reaction tube 203 to be parallel with surfaces of the wafers 200, i.e., in a horizontal direction. Due to the structure described above, a gas may be evenly supplied onto the wafers 200 and a thin film may be formed on the wafers 200 to a uniform thickness. Also, a gas flowing along surfaces of the wafers 200, i.e., a residual gas remaining after a reaction, flows in a direction of an exhaust mechanism, i.e., the exhaust pipe 231 which will be described below, but the direction in which the residual gas flows may be appropriately defined according to the location of the exhaust mechanism and is not limited to the vertical direction.

A chlorosilane-based source gas which is a first source gas containing first elements including a specific element and a halogen group (e.g., a first source gas containing at least silicon (Si) and a chloro group) is supplied into the process chamber 201 from the first gas supply pipe 232a via the MFC 241a, the valve 243a, and the first nozzle 249a. Here, the chlorosilane-based source gas means a gaseous chlorosilane-based source, e.g., a gas obtained by vaporizing a chlorosilane-based source that is in a liquid state at room temperature and pressure, or a chlorosilane-based source that is in a gas state at room temperature and pressure. Also, the chlorosilane-based source is a silane-based source containing a chloro group as a halogen group, and means a source containing at least silicon (Si) and chlorine (Cl). Here, the chlorosilane-based source may be understood as a type of halide. When the term ‘source’ is used in the present disclosure, it may be understood as a liquid source in a liquid state, a source gas in a gas state, or both of them. Thus, when the term ‘chlorosilane-based source’ is used in the present disclosure, it may be understood as a chlorosilane-based source in a liquid state, a chlorosilane-based source in a gas state, or both of them. For example, hexachlorodisilane (Si₂Cl₆, abbreviated to: HCDS) may be used as the chlorosilane-based source. When a liquid source, such as HCDS, which is in a liquid state at normal temperature and pressure, is used, the liquid source is vaporized using a vaporization system such as a vaporizer or a bubbler and supplied as a source gas (HCDS gas).

An aminosilane-based source gas which is a second source containing second elements that include a specific element and an amino group (amine group), e.g., a second source gas containing at least silicon (Si) and an amino group, is supplied into the process chamber 201 from the second gas supply pipe 232b via the MFC 241b, the valve 243b, and the second nozzle 249b. Here, the aminosilane-based source means a gas obtained by vaporizing an aminosilane-based source in a gas state, e.g., an aminosilane-based source that is in a liquid state at normal temperature and pressure, or an aminosilane-based source that is in a gas state at normal temperature and pressure. Also, the aminosilane-based source means a silane-based source containing an amino group (a silane-based source containing not only the amino group but also an alkyl group such as a methyl group, an ethyl group, or a butyl group), and a source containing at least silicon (Si), carbon (C), and nitrogen (N). Herein, the aminosilane-based source may be understood as an organic source or an organic aminosilane-based source. Also, when the term ‘aminosilane-based source’ is used in the present disclosure, it may be understood as an aminosilane-based source in a liquid state, an aminosilane-based source gas in a gas state, or both of them. The aminosilane-based source may be, for example, monoaminosilane (SiH₃R) containing one amino group in an empirical formula (In one molecule). Here, ‘R’ denotes a ligand, and is an amino group in which one nitrogen (N) atom coordinates with one or two hydrocarbon groups each containing one or more carbon (C) atoms [one or both of H atoms in an amino group expressed as NH₂ are substituted with a hydrocarbon group including one or more carbon (C) atoms]. When two hydrocarbon groups, each of which is a part of the amino group, coordinate with one N element, the hydrocarbon groups may be the same hydrocarbon groups or different hydrocarbon groups. Also, the hydrocarbon groups may each include an unsaturated bond such as a double bond or a triple bond. Also, the amino group may have a ring-shaped structure. For example, (ethylmethylamino)silane (SiH₃[N(CH₃(C₂H₅))]), (dimethylamino)silane (SiH₃[N(CH₃)₂]), (diethylpiperidino)silane (SiH₃[NC₅H₈(C₂H₅)₂]), etc. may be used as SiH₃R. When a liquid source, such as SiH₃R, that is in a liquid state at room temperature and pressure is used, the liquid source is vaporized using a vaporization system such as a vaporizer or a bubbler and is then supplied as a source gas (SiH₃R gas).

For example, a gas containing fluorine (F) (a fluorine-containing gas) is supplied as a cleaning gas into the process chamber 201 from the third gas supply pipe 232c via the MFC 241c, the valve 243c, the first gas supply pipe 232a, and the first nozzle 249a). For example, fluorine (F₂) gas, nitrogen fluoride (NF₃) gas, chlorine fluoride (ClF₃) gas, hydrogen fluoride (HF) gas, etc. may be used as the cleaning gas.

For example, nitrogen (N₂) gas is supplied as an inert gas into the process chamber 201 from the inert gas supply pipes 232d and 232e via the MFCs 241d and 241e, the valves 243d and 243e, the gas supply pipes 232a and 232b, and the nozzles 249a and 249b.

Also, when a gas as described above is supplied from each of these gas supply pipes, a first source gas supply system that supplies the first source gas containing the specific element and the halogen group, i.e., a chlorosilane-based source gas supply system, is configured using the first gas supply system. The chlorosilane-based source gas supply system is also referred to simply as a chlorosilane-based source supply system. Also, a second source gas supply system that supplies the second source gas containing the specific element and the amino group, i.e., an aminosilane-based source gas supply system, is configured using the second gas supply system. The aminosilane-based source gas supply system is also referred to simply as an aminosilane-based source supply system. A cleaning gas supply system is configured by the third gas supply system.

The exhaust pipe 231 is installed at the reaction tube 203 to exhaust an atmosphere in the process chamber 201. Referring to the cross-sectional view of FIG. 2, the exhaust pipe 231 is installed at a side opposite to sides of the reaction tube 203 in which the gas supply holes 250a of the first nozzle 249a and the gas supply holes 250b of the second nozzle 249b are formed, i.e., at a side opposite to the gas supply holes 250a and 250b with respect to the wafers 200. Also, referring to the longitudinal cross-sectional view of FIG. 1, the exhaust pipe 231 is installed below the positions at which the gas supply holes 250a and 250b are formed. Due to the structure described above, a gas supplied near the wafers 200 in the process container 201 through the gas supply holes 250a and 250b flows in a horizontal direction, i.e., a direction parallel to surfaces of the wafers 200, and then flows downward to be exhausted via the exhaust pipe 231. In the process chamber 201, a main gas flow occurs in the horizontal direction as described above.

A pressure sensor 245 serving as a pressure detector (pressure detection unit) configured to detect pressure in the process chamber 201 is connected to the exhaust pipe 231. A vacuum pump 246 serving as a vacuum exhaust device is connected to the exhaust pipe 231 via an auto pressure controller (APC) valve 244 serving as a pressure adjustor (pressure adjustment unit). Also, the APC valve 244 may be configured to vacuum-exhaust the inside of the process chamber 201 or suspend the vacuum-exhausting by opening/closing the APC valve 244 while the vacuum pump 246 is operated, and to adjust pressure in the process chamber 201 by adjusting a degree of opening of the APC valve 244 while the vacuum pump 246 is operated. An exhaust system mainly includes the exhaust pipe 231, the APC valve 244, and the pressure sensor 245. The exhaust system may further include the vacuum pump. The exhaust system is configured to vacuum-exhaust the inside of the process chamber 201 to a desired pressure (degree of vacuum) by adjusting the degree of opening of the APC valve 244 based on pressure information detected by the pressure sensor 245 while operating the vacuum pump 246.

Below the reaction tube 203, a seal cap 219 is installed as a furnace port lid that may air-tightly close a lower end aperture of the reaction tube 203. The seal cap 219 is configured to come in contact with a lower end of the reaction tube 203 from a lower portion thereof in a vertical direction. The seal cap 219 is formed of, for example, a metal, such as stainless steel, and has a disk shape. An O-ring 220 serving as a seal member that comes in contact with the lower end of the reaction tube 203 is installed on an upper surface of the seal cap 219. A rotating mechanism 267 that rotates the boat 217 as a substrate retainer (which will be described below) is installed at a side of the seal cap 219 opposite to the process chamber 201. A rotation shaft 255 of the rotating mechanism 267 is connected to the boat 217 while passing through the seal cap 219. The rotating mechanism 267 is configured to rotate the wafers 200 by rotating the boat 217. The seal cap 219 is configured to be vertically moved by a boat elevator 115 that is a lifting mechanism vertically installed outside the reaction tube 203. The boat elevator 115 is configured to load the boat 217 into or unload the boat 217 from the process chamber 201 by moving the seal cap 219 upward/downward. That is, the boat elevator 115 is configured as a transfer device (transfer mechanism) that transfers the boat 217, i.e., the wafers 200, into or out of the process chamber 201.

The boat 217 serving as a substrate supporter is formed of a heat-resistant material, e.g., quartz or silicon carbide, and is configured to support the wafers 200 in a state in which the wafers 200 are arranged in a concentrically multilayered structure in a horizontal posture. Below the boat 217, an insulating member 218 formed of a heat-resistant material, e.g., quartz or silicon carbide, is installed and configured to prevent heat generated from the heater 207 from being transferred to the seal cap 219. Also, the insulating member 218 may include a plurality of insulating plates formed of a heat-resistant material, e.g., quartz or silicon carbide, and an insulating plate holder that supports the plurality of insulating plates in a multilayered structure in a horizontal posture.

In the reaction tube 203, a temperature sensor 263 is installed as a temperature detector, and is configured to control an amount of current to be supplied to the heater 207 based on temperature information detected by the temperature sensor 263, so that the temperature in the process chamber 201 may have a desired temperature distribution. The temperature sensor 263 has an L-shape similar to the nozzles 249a and 249b, and is installed along an inner wall of the reaction tube 203.

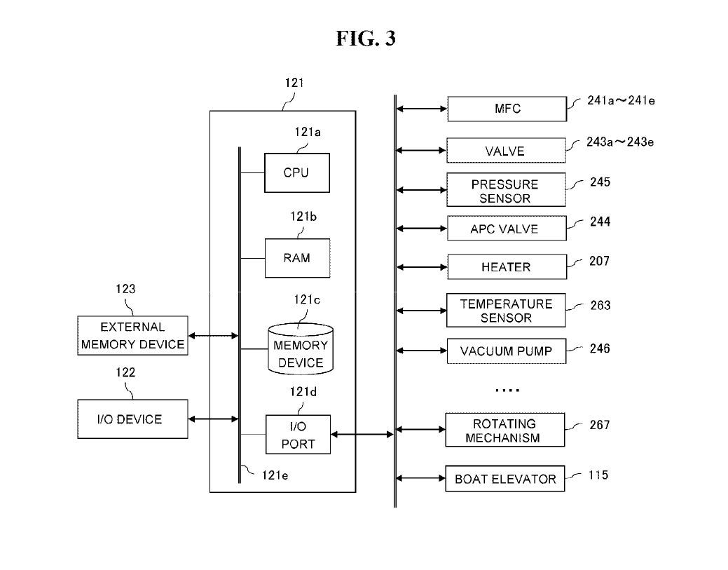

As illustrated in FIG. 3, a controller 121 which is a control unit (control means) is configured as a computer including a central processing unit (CPU) 121a, a random access memory (RAM) 121b, a memory device 121c, and an input/output (I/O) port 121d. The RAM 121b, the memory device 121c, and the I/O port 121d are configured to exchange data with the CPU 121a via an internal bus 121e. An I/O device 122 configured, for example, as a touch panel or the like is connected to the controller 121.

The memory device 121c is configured, for example, as a flash memory, a hard disk drive (HDD), or the like. In the memory device 121c, a control program for controlling an operation of a substrate processing apparatus, a process recipe including an order or conditions of substrate processing which will be described below, a cleaning recipe including an order and conditions of cleaning processing which will be described below, or a seasoning recipe including an order and conditions of a process of forming a pre-coating layer which will be described below is stored to be readable. Each of these recipes is a combination of sequences of a substrate processing process which will be described below to obtain a desired result when the sequences are performed by the controller 121, and acts as a program. Hereinafter, these recipes, the control program, etc. will also be referred to together simply as a ‘program.’ Also, when the term ‘program’ is used in the present disclosure, it should be understood as including only a recipe, only a control program, or both of the recipe and the control program. The RAM 121b is configured as a work area in which a program or data read by the CPU 121a is temporarily stored.

The I/O port 121d is connected to the MFCs 241a to 241e, the valves 243a to 243e, the pressure sensor 245, the APC valve 244, the vacuum pump 246, the heater 207, the temperature sensor 263, the rotating mechanism 267, the boat elevator 115, etc.

The CPU 121a is configured to read and execute the control program from the memory device 121c and to read these recipes from the memory device 121c according to a manipulation command received via the I/O device 122. Also, according to the read recipes, the CPU 121a is configured to control flow rates of various gases via the MFCs 241a to 241e; control opening/closing of the valves 243a to 243e; control the degree of pressure by opening/closing the APC valve 244 based on the pressure sensor 245 using the APC valve 244; control temperature using the heater 207 based on the temperature sensor 263; control driving/suspending of the vacuum pump 246; control the rotation and rotation speed of the boat 217 using the rotating mechanism 267; control upward/downward movement of the boat 217 using the boat elevator 115, etc.

The controller 121 is not limited to a dedicated computer and may be configured as a general-purpose computer. For example, the controller 121 according to the present embodiment may be configured by preparing an external memory device 123 storing a program as described above, e.g., a magnetic disk (a magnetic tape, a flexible disk, a hard disk, etc.), an optical disc (a compact disc (CD), a digital versatile disc (DVD), etc.), a magneto-optical (MO) disc, or a semiconductor memory (a Universal Serial Bus (USB) memory, a memory card, etc.), and then installing the program in a general-purpose computer using the external memory device 123. Also, means for supplying a program to a computer are not limited to using the external memory device 123. For example, a program may be supplied to a computer using communication means, e.g., the Internet or an exclusive line, without using the external memory device 123. The memory device 121c or the external memory device 123 may be configured as a non-transitory computer-readable recording medium. Hereinafter, the memory device 121c and the external memory device 123 may also be referred to together simply as a ‘recording medium.’ Also, when the term ‘recording medium’ is used in the present disclosure, it may be understood as only the memory device 121c, only the external memory device 123, or both the memory device 121c and the external memory device 123.

(2) Substrate Processing Process

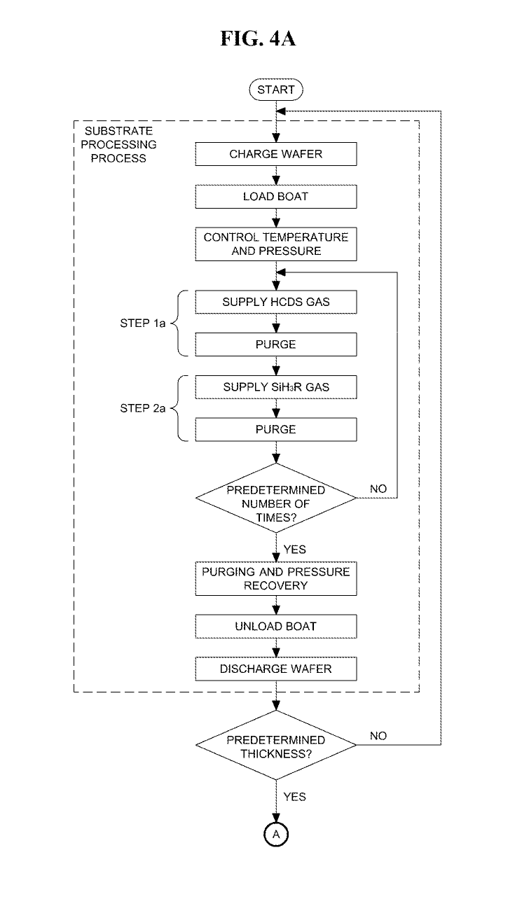

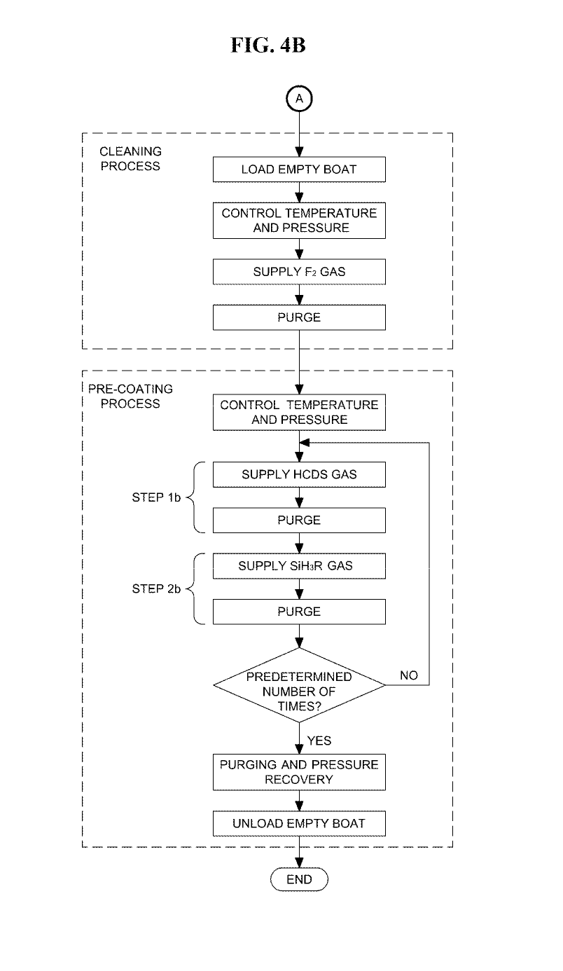

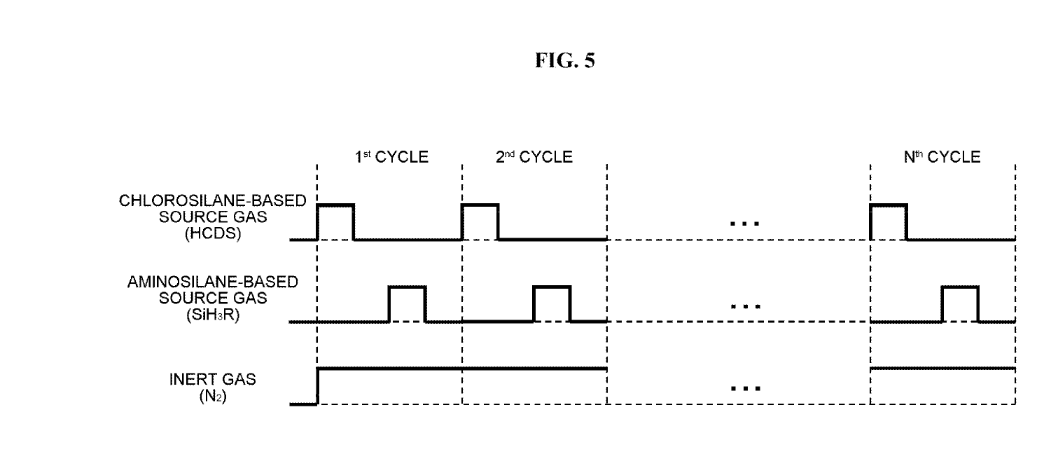

Next, an example of a sequence of a substrate processing process of forming a thin film including a specific element on a substrate using the process furnace of the substrate processing apparatus described above will be described as a process included in a process of manufacturing a semiconductor device with reference to FIGS. 4 and 5 below. FIGS. 4A and 4B are a flowchart of a substrate processing process, a cleaning process, and a pre-coating process according to an exemplary embodiment of the present invention. FIG. 5 is a timing chart illustrating gas supply timing in a substrate processing process according to an exemplary embodiment of the present invention. In the following description, operations of constitutional elements of a substrate processing apparatus are controlled by the controller 121.

In the substrate processing process according to the present embodiment, a process of loading a substrate into a process container in which a heat absorbing layer for saturating absorption of radiant heat radiated from a heating unit is formed on at least a portion of an outer wall, a process of forming a thin film on the substrate by heating the substrate in the process container by irradiating the substrate with radiant heat from the heating unit installed outside the process container and supplying a source gas onto the substrate in the process container, and a process of unloading the substrate from the process container after the thin film is formed on the substrate are performed.

In the process of forming the thin film on the substrate, the process container is heated by emitting radiant heat (primary radiant heat) into the process container from the heating unit installed outside the process container and saturating the absorption of the radiant heat radiated from the heating unit using the heat absorbing layer, and the substrate in the process container is heated using radiant heat (secondary radiant heat) that is mainly emitted from the heated process container and an atmosphere in the heated process container. In the present disclosure, the primary radiant heat may also be referred to as “first radiant heat”, and the secondary radiant heat may also be referred to as “second radiant heat”.

Also, in the process of forming the thin film on the substrate, a cycle including a process of forming a first layer containing a specific element and a halogen group by supplying a first source gas containing a specific element and a halogen group onto the substrate, and a process of forming a second layer by modifying the first layer by supplying a second source gas containing a specific element and an amino group onto the substrate is performed a predetermined number of times.

Here, performing the cycle including the process of forming the first layer and the process of forming the second layer the predetermined number of times includes performing the cycle once and performing the cycle a plurality of times. That is, it means performing the cycle at least once (a predetermined number of times).

A sequence of forming a film according to the present embodiment will now be described in detail. Here, an example of a process of forming a Si film including silicon (Si) as a specific element on the wafer 200 serving as a substrate using HCDS gas which is a chlorosilane-based source gas as a first source gas and SiH₃R gas which is an aminosilane-based source gas as a second source gas will be described.

When the term ‘wafer’ is used in the present disclosure, it should be understood as either the wafer itself, or both the wafer and a stacked structure (assembly) including a layer/film formed on the wafer (i.e., the wafer and the layer/film formed thereon may also be referred to collectively as the ‘wafer’). Also, when the expression ‘surface of the wafer’ is used in the present disclosure, it should be understood as either a surface (exposed surface) of the wafer itself or a surface of a layer/film formed on the wafer, i.e., an uppermost surface of the wafer as a stacked structure.

Thus, in the present disclosure, the expression ‘specific gas is supplied onto a wafer’ should be understood to mean that the specific gas is directly supplied onto a surface (exposed surface) of the wafer or that the specific gas is supplied onto a surface of a layer/film on the wafer, i.e., on the uppermost surface of the wafer as a stacked structure. Also, in the present disclosure, the expression ‘a layer (or film) is formed on the wafer’ should be understood to mean that the layer (or film) is directly formed on a surface (exposed surface) of the wafer itself or that the layer (or film) is formed on the layer/film on the wafer, i.e., on the uppermost surface of the wafer as a stacked structure.

Also, in the present disclosure, the term ‘substrate’ has the same meaning as the term ‘wafer.’ Thus, the term ‘wafer’ may be used interchangeably with the term ‘substrate.’

(Wafer Charging and Boat Loading)

When a plurality of wafers 200 are placed in the boat 217 (wafer charging), the boat 217 supporting the plurality of wafers 200 is lifted by the boat elevator 115 and loaded into the process chamber 201 (boat loading), as illustrated in FIG. 1. In this state, the lower end of the reaction tube 203 is air-tightly closed by the seal cap 219 via the O-ring 220.

(Pressure & Temperature Control)

The inside of the process chamber 201 in which the wafers 200 are present is vacuum-exhausted to have a desired pressure (degree of vacuum) by the vacuum pump 246. In this case, the pressure in the process chamber 201 is measured by the pressure sensor 245, and the APC valve 244 is feedback-controlled based on information regarding the measured pressure (pressure control). The vacuum pump 246 is kept operated at least until processing of the wafers 200 is completed. Also, the wafers in the process chamber 201 are heated to a desired temperature by the heater 207. In this case, an amount of current supplied to the heater 207 is feedback-controlled based on temperature information detected by the temperature sensor 263, so that the inside of the process chamber 201 may have a desired temperature distribution (temperature control). The heating of the inside of the process chamber 201 by the heater 207 is continuously performed at least until the processing of the wafers 200 is completed. Then, rotation of the boat 217 and the wafers 200 begins by the rotating mechanism 267. Also, the rotation of the boat 217 and the wafers 200 by the rotating mechanism 267 is continuously performed at least until the processing of the wafers 200 is completed.

Also, as described above, the heat absorbing layer 300 for saturating the absorption of the primary radiant heat radiated from the heater 207 is formed on the outer wall of the reaction tube 203 (side and ceiling portions of the outer wall of the reaction tube 203). The primary radiant heat radiated from the heater 207 is absorbed by the heat absorbing layer 300 and only a small portion thereof reaches the wafers 200 accommodated in the process chamber 201. As a result, the wafers 200 are heated mainly by the secondary radiant heat that is emitted from the reaction tube 203 heated when the heat absorbing layer 300 absorbs the primary radiant heat and that is then applied onto the wafer 200 and by heat transferred when the wafers 200 come in contact with an atmosphere in the heated reaction tube 203.

[Process of Forming a Si Film]

Then, the following two steps, i.e., steps 1a and 2a, are sequentially performed.

[Step 1a] (Supply of HCDS Gas)

The valve 243a of the first gas supply pipe 232a is opened to supply HCDS gas into the first gas supply pipe 232a. The flow rate of the HCDS gas flowing through the first gas supply pipe 232a is controlled by the MFC 241a. The HCDS gas, the flow rate of which is controlled, is supplied into the process chamber 201 via the gas supply holes 250a of the first nozzle 249a, and exhausted from the exhaust pipe 231. In this case, the HCDS gas is supplied onto the wafer 200. At the same time, the valve 243d is opened to supply an inert gas such as N₂ gas into the first inert gas supply pipe 232d. The flow rate of the N₂ gas flowing through the first inert gas supply pipe 232d is controlled by the MFC 241d. The N₂ gas, the flow rate of which is controlled, is supplied into the process chamber 201 together with the HCDS gas, and exhausted from the exhaust pipe 231.

Also, in this case, in order to prevent the HCDS gas from flowing into the second nozzle 249b, the valves 243e are opened to supply N₂ gas into the second inert gas supply pipe 232e. The N₂ gas is supplied into the process chamber 201 via the second gas supply pipe 232b and the second nozzle 249b, and exhausted from the exhaust pipe 231.

In this case, the pressure in the process chamber 201 is set to be within, for example, a range of 1 to 13,300 Pa, and preferably a range of 20 to 1,330 Pa, by appropriately controlling the APC valve 244. The supply flow rate of the HCDS gas controlled by the MFC 241a is set, for example, to be within a range of 1 to 1,000 sccm. The supply flow rates of the N₂ gas controlled by the MFCs 241d and 241e are set, for example, to be within a range of 100 to 10,000 sccm. A duration for which the HCDS gas is supplied onto the wafer 200, i.e., a gas supply time (gas irradiation time), is set to range, for example, from 1 to 120 seconds, and preferably 1 to 60 seconds.

If the temperature of the wafer 200 is less than 250° C., it is difficult for HCDS to be chemically adsorbed onto the wafer 200 and a practical film-forming rate may thus not be achieved. This problem may be overcome when the temperature of the wafer 200 is controlled to be 250° C. or more. Also, when the temperature of the wafer 200 is controlled to be 300° C. or more or 350° C. or more, HCDS may be more sufficiently adsorbed onto the wafer 200 and a more sufficient film-forming rate can be achieved. Also, when the temperature of the wafer 200 is greater than 700° C., a chemical vapor deposition (CVD) reaction becomes stronger (gas-phase reaction is dominant), and film thickness uniformity is likely to be degraded and may thus be difficult to control. When the temperature of the wafer 200 is controlled to be 700° C. or less, the film thickness uniformity may be prevented from being degraded and thus be controlled. In particular, when the temperature of wafer 200 is controlled to be 650° C. or less or 600° C. or less, a surface reaction becomes dominant, and the film thickness uniformity may be easily achieved and thus be easily controlled. Thus, when the temperature of the wafer 200 is within a range of 250 to 700° C., preferably a range of 300 to 650° C., and more preferably a range of 350 to 600° C., a process in step 1a (forming of a first layer which will be described below) may be performed.

However, when the temperature of the wafer 200 is less than 300° C., a modification action (modification action of the first layer) in step 2a which will be described in detail below is difficult to perform. The modification action in step 2a may be easily performed by setting the temperature of the wafer 200 to be 300° C. or more. Also, the modification action in step 2a may be more actively performed when the temperature of the wafer 200 is set to 350° C. or more. When the temperature of the wafer 200 exceeds 450° C., the modification action in step 2a is difficult to perform appropriately. That is, in order to efficiently and appropriately perform the process in step 2a, the temperature of the wafer 200 needs to be set to be within, for example, a range of 300° C. to 450° C., and preferably a range of 350° C. to 450° C.

As described above, preferable temperature conditions in steps 1a and 2a are different, and a preferable temperature range of performing step 2a falls within a preferable temperature range of performing step 1a. Here, temperature conditions of the wafer 200 in steps 1a and 2a are preferably set to be the same in order to improve the throughput of the process of forming a Si film by performing a cycle including steps 1a and 2a a predetermined number of times. That is, temperature conditions of the wafer 200 in step 1a are preferably the same as in step 2a. Thus, the temperature of the wafer 200 in step 1a may be within, for example, a range of 300° C. to 450° C., and preferably a range of 350° C. to 450° C. In this case, the process in step 1a (forming of the first layer) and the modification action (modification of the first layer) in step 2a may be efficiently and appropriately performed.

Under the conditions described above, the HCDS gas is supplied onto the wafer 200 to form a silicon-containing layer containing chlorine (Cl) as a first layer on the wafer 200 (an underlying film formed on the wafer 200) to a thickness of less than one atomic layer to several atomic layers. The silicon-containing layer containing chlorine (Cl) may include an adsorption layer of the HCDS gas, a silicon (Si) layer containing chlorine (Cl), or both of these layers.

Here, the silicon (Si) layer containing chlorine (Cl) generally refers to all layers including a continuous layer formed of silicon (Si) and containing chlorine (Cl), a discontinuous layer formed of silicon (Si) and containing chlorine (Cl), and a silicon (Si) thin film containing chlorine (Cl) and formed by overlapping the continuous layer and the discontinuous layer. The continuous layer formed of silicon (Si) and containing chlorine (Cl)) may also be referred to as a silicon thin film containing carbon (C) and chlorine (Cl). Also, silicon (Si) constituting the silicon (Si) layer containing chlorine (Cl) should be understood as including not only silicon (Si) from which a bond with chlorine (Cl) is not completely broken but also silicon (Si) from which the bond with chlorine (Cl) is completely broken.

Examples of the adsorption layer of HCDS gas include not only a chemical adsorption layer including continuous gas molecules of the HCDS gas but also a chemical adsorption layers including discontinuous gas molecules of the HCDS gas. That is, the adsorption layer of the HCDS gas includes a chemical adsorption layer formed of HCDS molecules to a thickness of one molecular layer or less than one molecular layer. Also, HCDS (Si₂Cl₆) molecules of the adsorption layer of the HCDS gas may have a chemical formula in which a bond between silicon (Si) and chlorine (Cl) is partially broken.

A layer having a thickness of less than one atomic layer means a discontinuously formed atomic layer, and a layer having a thickness of one atomic layer means a continuously formed atomic layer. A layer having a thickness of less than one molecular layer means a discontinuously formed molecular layer, and a layer having a thickness of one molecular layer means a continuously formed molecular layer.

Silicon (Si) is deposited on the wafer 200 to form a silicon (Si) layer containing chlorine (Cl) on the wafer 200 under conditions in which HCDS gas is self-decomposed (pyrolyzed), i.e., conditions causing a pyrolysis reaction of the HCDS gas. The HCDS gas is adsorbed onto the wafer 200 to form an adsorption layer of the HCDS gas on the wafer 200 under conditions in which HCDS gas is not self-decomposed (pyrolyzed), i.e., conditions that do not cause a pyrolysis reaction of the HCDS gas. A film-forming rate may be higher when the silicon (Si) layer containing chlorine (Cl) is formed on the wafer 200 than when the adsorption layer of the HCDS gas is formed on the wafer 200.

If the thickness of a silicon-containing layer containing chlorine (Cl) formed on the wafer 200 exceeds a thickness of several atomic layers, the modification action performed in step 2a which will be described below does not have an effect on the entire silicon-containing layer containing chlorine (Cl). The silicon-containing layer containing chlorine (Cl) that may be formed on the wafer 200 may have a minimum thickness of less than one atomic layer. Thus, the silicon-containing layer containing chlorine (Cl) may be set to have a thickness of less than one atomic layer to several atomic layers. Also, the modification action performed in step 2a (which will be described below) may be relatively increased by controlling the silicon-containing layer containing chlorine (Cl) to have a thickness not more than one atomic layer, i.e., a thickness of less than one atomic layer or of one atomic layer, thereby reducing a time required to perform the modification action in step 2. Also, a time required to form a silicon-containing layer containing chlorine (Cl) in Step 1a may be reduced. Accordingly, a process time per cycle may be reduced and a process time to perform a total of cycles may thus be reduced. That is, a film-forming rate may be increased. Also, film thickness uniformity may be controlled to be increased by controlling the silicon-containing layer containing chlorine (Cl) to have a thickness of one atomic layer or less.

(Removing of Remnant Gas)

After the first layer is formed, the valve 243a of the first gas supply pipe 232a is closed and the supply of the HCDS gas is stopped. In this case, the inside of the process chamber 201 is vacuum-exhausted by the vacuum pump 246 while the APC valve 244 of the exhaust pipe 231 is open, thereby eliminating the HCDS gas (that does not react or that has contributed to the formation of the first layer) remaining in the process chamber 201 from the process chamber 201. In this case, N₂ gas is continuously supplied as an inert gas into the process chamber 201 while the valves 243d and 243e are open. The N₂ gas acts as a purge gas to increase the effect of eliminating the HCDS gas (that does not react or that has contributed to the formation of the first layer) remaining in the process chamber 201 from the process chamber 201.

In this case, the gas remaining in the process chamber 201 may not be completely eliminated and the inside of the process chamber 201 may not be completely purged. When a small amount of gas remains in the process chamber 201, step 2a to be performed thereafter will not be badly influenced by the gas. In this case, the flow rate of the N₂ gas to be supplied into the process chamber 201 need not be high. For example, the inside of the process chamber 201 may be purged without causing step 2a to be badly influenced by the gas by supplying an amount of a gas corresponding to the capacity of the reaction tube 203 (process chamber 201). As described above, when the inside of the process chamber 201 is not completely purged, a purge time may be reduced to improve the throughput. Furthermore, the consumption of the N₂ gas may be suppressed to a necessary minimum level.

As the chlorosilane-based source gas, not only hexachlorodisilane (Si₂Cl₆, abbreviated as HCDS) gas but also an inorganic source gas, such as tetrachlorosilane, i.e., silicon tetrachloride (SiCl₄, abbreviated as STC) gas, trichlorosilane (SiHCl₃, abbreviated as TCS) gas, dichlorosilane (SiH₂Cl₂, abbreviated as DCS) gas, or monochlorosilane (SiH₃Cl, abbreviated as MCS) gas, may be used. As the inert gas, not only N₂ gas but also a rare gas, such as Ar gas, He gas, Ne gas, Xe gas, etc., may be used.

[Step 2a] (Supply of SiH₃R Gas)

After step 1a is terminated and the gas remaining in the process chamber 201 is eliminated, the valve 243b of the second gas supply pipe 232b is opened to supply SiH₃R gas into the second gas supply pipe 232b. The flow rate of the SiH₃R gas flowing in the second gas supply pipe 232b is adjusted by the MFC 241b. The SiH₃R gas, the flow rate of which is adjusted, is supplied from the gas supply holes 250b of the second nozzle 249b into the process chamber 201, and exhausted from the exhaust pipe 231. In this case, the SiH₃R gas is supplied onto the wafer 200. At the same time, the valve 243e is opened to supply N₂ gas as an inert gas into the second inert gas supply pipe 232e. The flow rate of the N₂ gas flowing in the second inert gas supply pipe 232e is adjusted by the MFC 241e. The N₂ gas, the flow rate of which is adjusted, is supplied into the process chamber 201 together with the SiH₃R gas, and exhausted from the exhaust pipe 231.

In this case, in order to prevent the SiH₃R gas from flowing into the first nozzle 249a, the valve 243d is opened to supply N₂ gas into the first inert gas supply pipe 232d. The N₂ gas is supplied into the process chamber 201 via the first gas supply pipe 232a and the first nozzle 249a, and is then exhausted from the exhaust pipe 231.

In this case, the APC valve 244 is appropriately adjusted to set the pressure in the process chamber 201 to be within a range of, for example, 1 to 13,300 Pa, and preferably a range of 20 to 1,330 Pa. The supply flow rate of the SiH₃R gas controlled by the MFC 241b is set to be within, for example, a range of 1 to 1,000 sccm. The supply flow rates of the N₂ gas controlled by the MFCs 241d and 241e are set to be within, for example, a range of 100 to 10,000 sccm. A duration for which the SiH₃R gas is supplied onto the wafer 200, i.e., a gas supply time (gas irradiation time), is set to be within, for example, a range of 1 to 120 seconds, and preferably a range of 1 to 60 seconds.

In this case, the temperature of the heater 207 is set such that the temperature of the wafer 200 falls within, for example, a range of 300 to 450° C., and preferably 350 to 450° C., similar to step 1a.

When the temperature of the wafer 200 is less than 300° C., the SiH₃R gas supplied onto the wafer 200 is not easily self-decomposed (pyrolyzed), thereby making it difficult to separate ligands (R) containing an amino group from silicon of the SiH₃R gas. That is, a number of ligands (R) to react with the first layer (the silicon-containing layer containing chlorine (Cl)) formed in step 1a, may be insufficient. As a result, it is difficult to cause abstraction reactions of abstracting chlorine (Cl) atoms from the first layer.

When the temperature of the wafer 200 is set to be 300° C. or more, the SiH₃R gas supplied onto the wafer 200 can be easily pyrolyzed, thereby enabling the ligands (R) containing an amino group to be easily separated from the silicon of the SiH₃R gas. When the separated ligands (R) react with a halogen group (Cl) in the first layer, an abstraction reaction of abstracting the halogen group (Cl) from the first layer may easily occur. When the temperature of the wafer 200 is set to 350° C. or more, the SiH₃R gas supplied onto the wafer 200 may be more actively pyrolyzed and the number of ligands (R) to be separated from the silicon of the SiH₃R gas may thus easily increase. Also, when the number of ligands (R) to react with chlorine (Cl) in the first layer increases, an abstraction reaction of the chlorine (Cl) from the first layer may more actively occur.

Heat energy of more than 450° C. is needed to bind the ligands (R) containing the amino group separated from the silicon of the SiH₃R gas with the silicon contained in the first layer (silicon-containing layer from which chlorine (Cl) is abstracted), i.e., silicon that gets a dangling bond after chlorine (Cl) is abstracted from the first layer (silicon electrons that become unpaired) or silicon that has contained a dangling bond (silicon electrons that are originally unpaired). Thus, when the temperature of the wafer 200 is set to 450° C. or less, the ligands (R) containing the amino group separated from the silicon of the SiH₃R gas may be prevented from binding with the silicon of the first layer that has or had the dangling bond. That is, when the temperature of the wafer 200 is set to 450° C. or less, the ligands (R) containing the amino group may be prevented from being included in the first layer. As a result, the content of impurities such as carbon (C) or nitrogen (N) in the result of modifying the first layer, i.e., the second layer which will be described below, may be reduced to a minimum level.

Also, when the temperature of the wafer 200 is set to be within a range of 350 to 450° C., silicon contained in the SiH₃R gas from which the ligands (R) are separated (i.e., silicon having a dangling bond contained in the SiH₃R gas) is likely to bind with the silicon of the first layer that has or had the dangling bond, thereby promoting formation of a Si—Si bond.

Also, when the temperature of the wafer 200 exceeds 450° C., the ligands (R) containing the amino group and separated from the silicon of the SiH₃R gas are likely to bind with the silicon of the first layer that has or had the dangling bond. That is, the ligands (R) containing the amino group are likely to be included in the first layer. Also, the content of carbon (C) or nitrogen (N) in the result of modifying the first layer, i.e., the second layer which will be described below, is likely to increase.

Thus, the temperature of the wafer 200 may be set to, for example, 300° C. to 450° C., and preferably, 350° C. to 450° C.

By supplying the SiH₃R gas onto the wafer 200 under the conditions described above, the first layer (silicon-containing layer containing chlorine (Cl)) formed on the wafer 200 in step 1a and the SiH₃R gas react with each other. That is, by supplying the SiH₃R gas onto the wafer 200 heated to the range of temperatures described above, ligands (R) containing an amino group are separated from the silicon of the SiH₃R gas, and react with chlorine (Cl) in the first layer, thereby abstracting the chlorine (Cl) from the first layer. Also, by heating the wafer 200 to the range of temperatures described above, the ligands (R) containing the amino group and separated from the silicon of the SiH₃R gas are prevented from binding with silicon that has or had a dangling bond of the first layer (silicon-containing layer from which chlorine (Cl) is abstracted). Also, the silicon containing the dangling bond when the ligands (R) are separated from the SiH₃R gas binds with the silicon that has or had the dangling bond of the first layer, thereby forming a Si—Si bond. Thus, in step 1a, the first layer formed on the wafer 200 is changed (modified) into a second layer containing silicon (Si) and having an extremely low content of impurities such as chlorine (Cl), carbon (C), or nitrogen (N). The second layer is a silicon (Si) layer having a thickness of less than one atomic layer to several atomic layers, formed of elemental silicon, and having an extremely low content of impurities such as chlorine (Cl), carbon (C), or nitrogen (N). The crystal structure of the Si layer has an amorphous state. The Si layer containing carbon (C) may also be referred to as an amorphous silicon layer (a-Si layer).

When a Si layer is formed as the second layer, most chlorine (Cl) of the first layer that has yet to be modified and a most of the ligands (R) containing an amino group of the SiH₃R gas react with each other to form a gas-phase reaction product, e.g., sodium amide, during the modification of the first layer using the SiH₃R gas, and are then exhausted from the inside of the process chamber 201 via the exhaust pipe 231. Thus, the content of impurities such as chlorine (Cl), carbon (C), or nitrogen (N) in the result of modifying the first layer, i.e., the second layer, may decrease. Also, when SiH₃R gas is used as the aminosilane-based source gas, the number of amino groups included in the empirical formula (or one molecule) of the SiH₃R gas is low, i.e., the content of carbon (C) or nitrogen (N) contained in the composition of the SiH₃R gas is low. Thus, the content of impurities such as carbon (C) or nitrogen (N) contained in the result of modifying the first layer, i.e., the second layer, may be easily decreased. In particular, the content of nitrogen (N) in the second layer may be greatly decreased.

(Removing of Remnant Gas)

After the second layer is formed, the valve 243b of the second gas supply pipe 232b is closed and the supply of the SiH₃R gas is stopped. In this case, the inside of the process chamber 201 is vacuum-exhausted by the vacuum pump 246 while the APC valve 244 of the exhaust pipe 231 is open, thereby eliminating the SiH₃R gas (that does not react or that contributes to the formation of the second layer) or byproducts remaining in the process chamber 201 from the process chamber 201. In this case, N₂ gas is continuously supplied as an inert gas into the process chamber 201 while the valves 243d and 243e are open. The N₂ gas acts as a purge gas to increase the effect of eliminating the SiH₃R gas (that does not react or that has contributed to formation of the second layer) or by-products remaining in the process chamber 201 from the process chamber 201.

In this case, the gas remaining in the process chamber 201 may not be completely eliminated and the inside of the process chamber 201 may not be completely purged. When a small amount of a gas remains in the process chamber 201, step 1a to be performed thereafter will not be badly influenced by the gas. In this case, the flow rate of the N₂ gas to be supplied into the process chamber 201 need not be high. For example, the inside of the process chamber 201 may be purged without causing step 1a to be badly influenced by the gas by supplying an amount of a gas corresponding to the capacity of the reaction tube 203 (process chamber 201). As described above, when the inside of the process chamber 201 is not completely purged, a purge time may be reduced to improve the throughput. Furthermore, the consumption of the N₂ gas may be suppressed to a necessary minimum level.

As the aminosilane-based source, not only monoaminosilane (SiH₃R) gas but also an organic source, such as diaminosilane (SiH₂RR′), triaminosilane (SiHRR′R″), or tetraminosilane (SiRR′R″R′″), may be used. Here, R, R′, R″, and R′″ each denote a ligand representing an amino group in which one or two hydrocarbon groups each including one nitrogen (N) atom and at least one carbon (C) atom coordinate [in which one side or both of hydrogen (H) atoms in an amino group expressed as NH₂ are substituted with a hydrocarbon group including one or more carbon (C) atoms]. When two hydrocarbon groups, each of which is a part of an amino group, coordinate with one nitrogen (N) atom, the two hydrocarbon groups may be the same hydrocarbon groups or different hydrocarbon groups. Also, each of the hydrocarbon groups may include an unsaturated bond such as a double bond or a triple bond. Also, the amino groups represented by R, R′, R″, and R′″ may be the same amino groups or different amino groups. Also, the amino groups may have a ring-shaped structure. For example, bis(diethylamino)silane (SiH₂[N(C₂H₅)₂]₂, abbreviated as BDEAS), bis(tertiary butylamino)silane (SiH₂[NH(C₄H₉)]₂, abbreviated as BTBAS), bis(diethylpiperidino)silane (SiH₂[NC₅H₈(C₂H₅)₂]₂, abbreviated as BDEPS), etc. may be used as SiH₂RR′. For example, tris(diethyl amino)silane (SiH[N(C₂H₅)₂]₃, abbreviated as 3DEAS), tris(dimethylamino)silane (SiH[N(CH₃)₂]₃, abbreviated as 3DMAS), etc. may be used as SiHRR′R″. Also, for example, tetrakis(diethylamino)silane (Si[N(C₂H₅)₂]₄, abbreviated as 4DEAS), tetrakis(dimethylamino)silane (Si[N(CH₃)₂]₄, abbreviated as 4DMAS), etc. may be used as SiRR′R″R′″.

Also, an organic source gas having an empirical formula in which the number of ligands containing an amino group is less than or equal to ‘2’ or the number of ligands containing a halogen group in an empirical formula of a chlorosilane-based source gas is preferably used as the aminosilane-based source gas.

For example, when HCDS (Si₂Cl₆) gas, STC (SiCl₄) gas, TCS (SiHCl₃) gas, or DCS (SiH₂Cl₂) gas each having an empirical formula in which the number of ligands (Cl) containing a halogen group is equal to or greater than ‘2’ is used as a chlorosilane-based source gas, monoaminosilane (SiH₃R) gas having an empirical formula in which the number of ligands (R) containing an amino group is ‘1’ or diaminosilane (SiH₂RR′) gas having an empirical formula in which the number of ligands (R) containing an amino group is ‘2’ is preferably used as the aminosilane-based source gas. When MCS (SiH₃Cl) gas having an empirical formula in which the number of ligands (R) containing a halogen group is ‘1’ is used as a chlorosilane-based source gas, monoaminosilane (SiH₃R) gas having an empirical formula in which the number of ligands (R) containing an amino group is ‘1’ is preferably used as an aminosilane-based source gas.

Also, the number of ligands (R) containing an amino group in the empirical formula of the aminosilane-based source gas is preferably less than that of ligands (Cl) containing a halogen group in the empirical formula of the chlorosilane-based source gas. Thus, when DCS having two ligands (Cl) containing a halogen group in an empirical formula is used as the chlorosilane-based source gas, monoaminosilane gas having one ligand (R) containing an amino group in an empirical formula is preferably used as the aminosilane-based source gas, rather than diaminosilane gas having two ligands (R) containing an amino group in an empirical formula.

Also, the number of ligands (R) containing an amino group in the empirical formula of the aminosilane-based source gas is more preferably ‘1.’ Thus, monoaminosilane gas is more preferably used as the aminosilane-based source gas, rather than diaminosilane gas. In this case, HCDS gas, STC gas, TCS gas, or DCS gas each having an empirical formula in which the number of ligands (Cl) containing a halogen group is equal to or greater than ‘2’ is more preferably used as the chlorosilane-based source gas, so that the number of ligands (R) containing an amino group in the empirical formula of the aminosilane-based source gas may be less than that of ligands (Cl) containing a halogen group in the empirical formula of the chlorosilane-based source gas.

Thus, in step 2a, the number of Cl contained in the first layer that has yet to be modified is greater than the number of ligands (R) having an amino group and contained in the SiH₃R gas supplied onto the first layer (Si-containing layer containing Cl). In this case, most of the ligands (R) having an amino group and contained in the SiH₃R gas react with Cl contained in the first layer that has yet to be modified (i.e., Cl, the number of which is greater than the number of the ligands (R) having an amino group) to form a gas-phase reaction product, e.g., sodium amide, during the modification of the first layer and are then discharged from the process chamber 201 via the exhaust pipe 231. That is, most of the ligands (R) having an amino group and contained in the SiH₃R gas are not included in the result of modifying the first layer, i.e., the second layer, are discharged from the process chamber 201, and are then lost. As a result, the result of modifying the first layer, i.e., the second layer, may be changed (modified) into a Si layer in which the content of impurities such as carbon (C) and nitrogen (N) is less than in the second layer.

As the inert gas, not only N₂ gas but also a rare gas, such as Ar gas, He gas, Ne gas, or Xe gas, may be used.

(Performing a Cycle a Predetermined Number of Times)

A silicon (Si) film formed of elemental silicon and having an extremely low content of impurities such as chlorine (Cl), carbon (C), or nitrogen (N) may be formed on the wafer 200 to a predetermined thickness by performing a cycle including steps 1a and 2a described above at least once (a predetermined number of times). The crystal structure of the Si film has an amorphous state. The Si film may also be referred to as an amorphous silicon film (a-Si film). The cycle described above is preferably performed a plurality of times. That is, a thickness of an Si layer to be formed per cycle may be set to be less than a desired thickness and the cycle may be performed a plurality of times until the Si film may have the desired thickness.

When the cycle is performed a plurality of times, ‘a specific gas being supplied onto the wafer 200’ in each step after the cycle is performed at least twice’ means that the specific gas is supplied on a layer formed on the wafer 200, i.e., on the uppermost surface of the wafer 200 as a stacked structure. ‘A specific layer being formed on the wafer 200’ means that the specific layer is formed on a layer formed on the wafer 200, i.e., on the uppermost surface of the wafer 200 as a stacked structure. This has been described above, and also applies to modified examples and other embodiments which will be described below.

(Purging and Atmospheric Pressure Recovery)

After the Si film is formed to the predetermined thickness, the valves 243d and 243e are opened to supply N₂ gas as an inert gas into the process chamber 201 via the inert gas supply pipes 232d and 232e and then the N₂ gas is exhausted from the exhaust pipe 231. The N₂ gas acts as a purge gas to purge the inside of the process chamber 201 with the inert gas, thereby eliminating a gas or by-products remaining in the process chamber 201 from the process chamber 201 (purging). Thereafter, an atmosphere in the process chamber 201 is replaced with the inert gas (inert gas replacement), and the pressure in the process chamber 201 is recovered to normal pressure (atmospheric pressure recovery).

(Boat Unloading and Wafer Discharging)

Then, the seal cap 219 is moved downward by the boat elevator 115 to open the lower end of the reaction tube 203, and the processed wafers 200 are unloaded to the outside of the reaction tube 203 from the lower end of the reaction tube 203 while being supported by the boat 217 (boat unloading). Thereafter, the processed wafers 200 are unloaded from the boat 217 (wafer discharging).

(3) Cleaning Process

A method of cleaning the inside of the process chamber 201 will now be described. In the following description, operations of constitutional elements of the substrate processing apparatus are controlled by the controller 121.

When the substrate processing process described above is performed, a thin film including a Si film or the like is formed inside the process chamber 201, i.e., on an inner wall of the reaction tube 203 or a surface of the boat 217 (hereinafter, the thin film may also be referred to as a ‘deposited film’). The deposited film is accumulated and gradually becomes thicker when the substrate processing process is repeatedly performed. The deposited film may peel off due to vibration occurring when the boat 217 is rotated or transferred or thermal expansion/contraction when the temperature of the process chamber 201 increases/decreases, thereby generating particles (foreign substances). Thus, a cleaning process is performed inside the process chamber 201 when the thickness of the deposited film becomes equal to a predetermined level. The cleaning process may be performed by solely supplying F₂ gas or F₂ gas diluted with an inert gas, for example, as a cleaning gas into the process chamber 201 heated to a predetermined temperature in a state in which the wafers 200 are not accommodated in the process chamber 201. The cleaning process will be described in detail below.

The empty boat 217, i.e., the boat 217 into which no wafer 200 is loaded, is lifted by the boat elevator 115 and loaded into the process chamber 201 (loading of empty boat). In this state, the lower end portion of the reaction tube 203 is air-tightly blocked with the seal cap 219 via the O-ring 220.

The pressure and temperature in the process chamber 201 are controlled according to a process sequence similar to that of the substrate processing process described above. The pressure and temperature in the process chamber 201 are continuously controlled at least until the cleaning of the inside of the process chamber 201 is completed (pressure and temperature control). Then, the boat 217 begins to be rotated by the rotating mechanism 267. Alternatively, rotation of the boat 217 may be omitted.

The valve 243c of the third gas supply pipe 232c is opened to supply F₂ gas into the third gas supply pipe 232c in a state in which the pressure and temperature in the process chamber 201 are maintained at predetermined pressure and temperature levels (supply of F₂ gas). The flow rate of the F₂ gas flowing in the third gas supply pipe 232c is adjusted by the MFC 241c. The flow rate controlled F₂ gas passes through the first gas supply pipe 232a, is supplied into the process chamber 201 via the gas supply holes 250a in the first nozzle 249a, and is then exhausted from the exhaust pipe 231. At the same time, the valve 243d may be opened to flow an inert gas such as N₂ gas into the first inert gas supply pipe 232d so as to dilute the F₂ gas which is a cleaning gas. The flow rate of the N₂ gas flowing in the first inert gas supply pipe 232d is adjusted by the MFC 241d. The flow rate adjusted N₂ gas is supplied into the process chamber 201 together with the cleaning gas, and exhausted from the exhaust pipe 231. The concentration of the F₂ gas may be controlled by adjusting the supply flow rate of the N₂ gas.

In this case, the valve 243e is opened to supply N₂ gas into the second inert gas supply pipe 232e to prevent the F₂ gas from flowing into the second nozzle 249b. The N₂ gas is supplied into the process chamber 201 via the second gas supply pipe 232b and the second nozzle 249b and exhausted from the exhaust pipe 231.

The F₂ gas or the diluted F₂ gas introduced into the process chamber 201 comes in contact with the deposited film formed on the inner wall of the reaction tube 203 or the surface of the boat 217 when this gas passes through the inside of the process chamber 201. In this case, the deposited film is removed due to a thermochemical reaction. That is, the deposited film is removed by active species generated when the F₂ gas is pyrolyzed and an etching reaction of the deposited film. Also, in this case, the F₂ gas or the diluted F₂ gas also comes in contact with a deposit including silicon (Si) accumulated on the inner wall of the first nozzle 249a when this gas passes through the first nozzle 249a, thereby removing the deposit containing the silicon (Si).

When a predetermined etching time of the deposited film passes and the inside of the process chamber 201 is completed, the valve 243c is closed to suspend the supply of the F₂ gas or the diluted F₂ gas into the process chamber 201. Thereafter, the inside of the process chamber 201 is purged with an inert gas according to a process sequence similar to that of the substrate processing process described above to remove the F₂ gas or byproducts remaining in the process chamber 201 from the process chamber 201 (purging).

In the cleaning process, for example, a temperature in the process chamber is 350° C. to 500° C.; a pressure in the process chamber is 6,650 Pa to 26,600 Pa, and preferably 13,300 Pa to 19,950 Pa; the supply flow rate of the F₂ gas is 0.5 slm to 5 slm; and the supply flow rate of the N₂ gas is 1 slm to 20 slm, as conditions of etching the deposited film. The deposited film may be etched by maintaining the etching conditions described above constant.

(4) Pre-Coating Process

After the cleaning process described above is completed, a quartz member in the process chamber 201, i.e., the inner wall of the reaction tube 203 or the surface of the boat 217, may be damaged by etching. Foreign substances (particles) such as quartz powder may be generated from the damaged quartz member and cause the quality of substrate processing to be degraded in the substrate processing process performed after the cleaning process. Thus, when the cleaning process is performed, a pre-coating process is performed to form a pre-coating layer to a predetermined thickness on a surface of the quartz member in the process chamber 201. The pre-coating layer may be formed by heating the inside of the process chamber 201 and supplying a source gas into the heated process chamber 201 in a state in which the wafers 200 are not accommodated in the process chamber 201. The pre-coating process will be described in detail below.

The pressure and temperature in the process chamber 201 are controlled according to a process sequence and process conditions similar to those of the substrate processing process described above, in a state in which the empty boat 217 is loaded into the process chamber 201 (pressure and temperature control). The pressure and temperature in the process chamber 201 are continuously controlled at least until the formation of the pre-coating layer is completed. Then, the boat 217 begins to be rotated by the rotating mechanism 267. Alternatively, rotation of the boat 217 may be omitted.

Next, a cycle including steps 1b and 2b similar to steps 1a and 2a included in the substrate processing process described above is performed at least once (a predetermined number of times). Thus, a layer formed of elemental silicon and having a predetermined thickness and an extremely low content of impurities such as chlorine (Cl), carbon (C), or nitrogen (N) is formed as the pre-coating layer on the inner wall of the reaction tube 203 or the surface of the boat 217.

After the formation of the pre-coating layer is completed, the inside of the process chamber 201 is purged with an inert gas according to a process sequence similar to that of the substrate processing process described above to remove a gas or byproducts remaining in the process chamber 201 from the process chamber 201 (purging). Thereafter, an atmosphere in the process chamber 201 is replaced with the inert gas (inert gas replacement), and the pressure in the process chamber 201 is returned to normal pressure (atmospheric pressure recovery).

Thereafter, the seal cap 219 is moved downward by the boat elevator 115 to open the lower end portion of the reaction tube 203 and the empty boat 217 is unloaded from the lower end portion of the reaction tube 203 to the outside of the reaction tube 203 (unloading of empty boat).

Then, the substrate processing process described above is resumed. Foreign substances may be suppressed from being generated from the damaged quartz member by performing the cleaning process by forming the pre-coating layer. Thus, the quality of substrate processing may be improved in the substrate processing process performed after the cleaning process. When the pre-coating layer is formed to suppress foreign substances from being generated from the damaged quartz member, the pre-coating layer may be formed to a thickness of, for example, about 200 Å to 300 Å. The pre-coating process may not be performed when the quartz member is damaged to a low level when the cleaning process is performed.

(5) Effect of the Present Embodiment

According to the present embodiment, one or more effects which will be described below may be obtained.

According to the present embodiment, the heat absorbing layer 300 formed on the outer wall of the reaction tube 203 acts to saturate absorption of primary radiant heat radiated from the heater 207. Thus, the wafers 200 are mainly heated by radiant heat (secondary radiant heat) emitted from the reaction tube 203, which is heated when the heat absorbing layer 300 absorbs the primary radiant heat, and applied onto the wafer 200 and heat transferred when the wafers 200 come in contact with an atmosphere in the heated reaction tube 203.

As a result, the heating of the wafers 200 does not mainly depend on the presence or thickness of the deposited film formed on the inner wall of the reaction tube 203, i.e., a thin film having a property of absorbing or reflecting the primary radiant heat. That is, even if the deposited film is formed on the inner wall of the reaction tube 203 when the substrate processing process is performed, conditions of heating the wafers 200 may be maintained constant in this process (one-batch processing). Also, even if the thickness of the deposited film gradually increases when the substrate processing process is performed a plurality of times, the conditions of heating the wafers 200 may be maintained constant while the substrate processing process is performed the plurality of times (in multiple batch processings). Also, even if the deposited film is removed at a time from the inside of the reaction tube 203, the conditions of heating the wafers 200 may be maintained constant before and after the deposited film is removed. That is, the quality of substrate processing may be improved by maintaining the conditions of heating the wafers 200 constant.

When the heat absorbing layer 300 is not formed on the outer wall of the reaction tube 203, a pre-coating layer having the same optical properties as the deposited film removed in the cleaning process may be formed on an inner wall of the reaction tube 203 beforehand after the cleaning process is performed and before the substrate processing process begins, so that the conditions of heating the wafers 200 may be maintained constant before and after the cleaning process is performed. However, in this case, the pre-coating layer formed on the inner wall of the reaction tube 203 needs to be formed to a thickness suitable for saturating absorption of the primary radiant heat radiated from the heater 207. In detail, when the pre-coating layer is formed of amorphous silicon or polysilicon, the pre-coating layer needs to be formed to, for example, a thickness of 1 μm or more. If the pre-coating layer having the thickness described above is formed whenever the cleaning process is performed, a film-forming yield may be lowered, thus increasing film-forming costs. In particular, there are cases in which the cleaning process needs to be performed whenever the substrate processing process is performed, according to the type of a thin film to be formed on the wafer 200 or process conditions. In such cases, the problems described above are severe. Also, when the pre-coating layer is formed thickly beforehand, a time period until a next cleaning process is performed, i.e., until the thickness of the deposited film including the pre-coating layer becomes equal to a predetermined level, becomes shorter and the frequency of cleaning consequently increases, thereby greatly lowering an operation rate of the substrate processing apparatus.

Thus, the heat absorbing layer 300 according to the present embodiment is formed on the outer wall of the reaction tube 203, i.e., a location that is not influenced by the cleaning process. Thus, the conditions of heating the wafers 200 may be easily maintained constant before and after the cleaning process is performed. Also, as described above, when the pre-coating layer is formed in the reaction tube 203 to suppress foreign substances from being generated from the quartz member in the process chamber 201, the pre-coating layer may be formed to a thin thickness of, for example, 200 Å to 300 Å (0.02 μm to 0.03 μm). When the pre-coating layer is formed in the reaction tube 203 to saturate absorption of primary radiant heat radiated from the heater 207, the pre-coating layer may be formed to a very thin thickness that is far less than, for example, 1 μm. Thus, even if the pre-coating process is performed whenever the cleaning process is performed, a film-forming yield may be prevented from being lowered and film-forming costs may be decreased. Also, since the pre-coating layer may be formed to a thin thickness, a time period until a next cleaning process is performed may be increased and the frequency of cleaning may be decreased, thereby increasing an operation rate of the substrate processing apparatus.

Also, according to the present invention, the effects described above may be obtained with low costs by simply forming the heat absorbing layer 300 on the outer wall of the reaction tube 203, i.e., without greatly modifying and dissembling the existing substrate processing apparatus. The heat absorbing layer 300 may be formed by chemical vapor deposition (CVD) by accommodating and heating the reaction tube 203 in the process container and supplying a predetermined source gas such as silane (SiH₄) gas onto an outer wall of the reaction tube 203, or by plunging the reaction tube 203 into a plating solution and plating an outer wall of the reaction tube 203 with a predetermined metal. Otherwise, the heat absorbing layer 300 may be formed by applying a heat-resistant paint having predetermined optical features onto the outer wall of the reaction tube or by adhering a sheet type heat-resistant material having predetermined optical features onto the outer wall of the reaction tube 203. Otherwise, the heat absorbing layer 300 may be formed by physically processing the outer wall of the reaction tube 203 to have a rough surface having predetermined optical features, or by chemically processing the outer wall of the reaction tube 203 to have such a rough surface.

### Other Embodiments of the Present Invention

Although embodiments of the present invention have been described above in detail, the present invention is not limited thereto and may be embodied in various different forms without departing from the scope of the present invention.

For example, in the previous embodiments, a case in which a chlorosilane-based source gas and an aminosilane-based source gas are sequentially supplied onto the wafers 200 has been described, but these source gases may be supplied in a reversed order. That is, the aminosilane-based source gas may be supplied and then the chlorosilane-based source gas may be supplied. That is, one of the chlorosilane-based source gas and the aminosilane-based source gas may be first supplied and then the other source gas may be supplied. As described above, the quality of a thin film to be formed may be changed by changing the order in which the source gases are supplied.

Also, in the previous embodiments, a case in which a chlorosilane-based source gas is supplied onto the wafers 200 and then an aminosilane-based source gas is supplied onto the wafers 200 to form a Si film has been described above. However, a CVD reaction may be caused to occur by simultaneously supplying the chlorosilane-based source gas and the aminosilane-based source gas onto the wafers 200. As described above, the effects according to the previous embodiments may also be derived even when the chlorosilane-based source gas and the aminosilane-based source gas are simultaneously supplied onto the wafers 200. However, as in the previous embodiments, the controllability of the thickness of a thin film may be improved by alternately supplying the chlorosilane-based source gas and the aminosilane-based source gas by purging the inside of the process chamber 201 between when the chlorosilane-based source gas is supplied and when the aminosilane-based source gas is supplied, so that the chlorosilane-based source gas and the aminosilane-based source gas can be appropriately reacted under a condition causing a surface reaction to be dominant.

Also, in the previous embodiment, a case in which the chlorosilane-based source gas and the aminosilane-based source gas are used has been described, but a silane-based source gas having halogen-based ligands rather than chloro-based ligands may be used instead of the chlorosilane-based source gas. For example, a fluorosilane-based source gas may be used instead of the chlorosilane-based source gas. Here, the fluorosilane-based source gas means a silane-based source gas that contains a fluoro group as a halogen group and that includes at least silicon (Si) and fluorine (F). As the fluorosilane-based source gas, for example, a silicon fluoride gas such as tetrafluorosilane, i.e., silicontetrafluoride (SiF₄) gas, or hexafluorosilane (Si₂F₆) gas, may be used. In this case, the fluorosilane-based source gas and an aminosilane-based source gas may be sequentially supplied onto the wafers 200 in the process chamber 201, or the aminosilane-based source gas and the fluorosilane-based source gas may be sequentially supplied onto the wafers 200. However, a chlorosilane-based source gas is preferably used as the silane-based source gas including a halogen group, in consideration of steam pressure caused by a source gas or byproducts generated in step 2a.

Also, a case in which monoaminosilane (SiH₃R) gas is used as the second source gas (aminosilane-based source gas) was described in the previous embodiment, but the present invention is not limited thereto. That is, for example, an organic source gas, such as diaminosilane (SiH₂RR′) gas, triaminosilane (SiHRR′R″) gas, or tetraminosilane (SiRR′R″R′″) gas, may be used as the second source gas. That is, a source gas having two, three, or four amino groups in an empirical formula (In one molecule) may be used as the second source gas. As described above, even if a source gas having a plurality of amino groups in an empirical formula (In one molecule) is used as the second source gas, a Si film having a low content of impurities such as carbon (C) or nitrogen (N) may be formed in a low-temperature region.

However, the less the number of amino groups included in the empirical formula of the second source gas, i.e., the less the content of carbon (C) or nitrogen (N) included in the composition of the second source gas, the more easily the amount of impurities such as carbon (C) or nitrogen (N) contained in the first layer can be decreased, thereby enabling a Si film having an extremely low content of impurities to be formed. That is, SiH₃R, SiH₂RR′, or SiHRR′R″ is preferably used as the second source gas rather than SiRR′R″R′″ since the amount of impurities that is to be contained in the Si film can be easily decreased. Also, SiH₃R or SiH₂RR′ is more preferably used as the second source gas rather than SiHRR′R″ since the amount of impurities that is to be contained in the Si film can be easily decreased. Also, SiH₃R is more preferably used as the second source gas rather than SiH₂RR′ since the amount of impurities that is to be contained in the Si film can be easily decreased.

Also, in the previous embodiments, a case in which an a-Si film is formed as a Si film by setting the temperature of the wafers 200 to be within, for example, a range of 300° C. to 450° C., and preferably a range of 350° C. to 450° C., in a process of forming a Si film was described, but the present invention is not limited thereto. For example, a Si film having a polycrystalline state, i.e., a polysilicon film (poly-Si film), may be formed as the Si film by setting the temperature of the wafers 200 to be within, for example, a range of 600° C. to 700° C. in the process of forming a Si film.

Also, in the previous embodiments, a case in which a Si film is formed by alternately supplying two different silane-based gases, i.e., a chlorosilane-based source gas and an aminosilane-based source gas, in the process of forming a Si film was described, but the present invention is not limited thereto. For example, a Si film may be formed by CVD and using one silane-based gas such as SiH₄ gas. In this case, an a-Si film or a poly-Si film may be formed as the Si film by setting the temperature of the wafers 200 to be within, for example, a range of 300° C. to 800° C. in the process of forming a Si film.

That is, the present invention is applicable to forming various Si-based thin films.

Also, a technique of forming a device having high processability may be provided by using a silicon film formed according to an embodiment of the present invention as an etch stopper layer. The silicon film formed according to an embodiment of the present invention is preferably applicable to various fields, including, for example, a floating gate electrode or a control gate electrode of a semiconductor memory device, channel silicon, a transistor gate electrode, a capacitor electrode of a dynamic random access memory (DRAM), an STI liner, a solar cell, etc.

Although cases in which a silicon film containing silicon which is a semiconductor element is formed as a thin film including a specific element have been described in the previous embodiments, the present invention is also applicable to cases in which a metal thin film containing a metal element such as titanium (Ti), zirconium (Zr), hafnium (Hf), tantalum (Ta), aluminum (Al), molybdenum (Mo), tungsten (W), or cobalt (Co) is formed.

In this case, a film may be formed using a source gas (first source gas) containing a metal element and a halogen group and a source gas (second source gas) containing a metal element and an amino group instead of the chlorosilane-based source gas and the aminosilane-based source used in the previous embodiment, according to a film-forming sequence similar to that in the previous embodiment. As the first source gas, for example, a source gas containing a metal element and a chloro group or a source gas containing a metal element and a fluoro group may be used.

That is, in this case, in a process of forming a metal-based thin film on the wafer 200, a cycle including a process of forming a first layer containing a metal element and a halogen group by supplying a first source gas containing a metal element and a halogen group onto the wafer 200 and a process of forming a second layer by modifying the first layer by supplying a second source gas containing a metal element and an amino group onto the wafer 200 is performed a predetermined number of times.

For example, when a Ti film which is a Ti-based thin film formed of a single Ti element is formed as a metal-based thin film, a source gas containing Ti and a chloro group such as titanium tetrachloride (TiCl₄) gas or a source gas containing Ti and a fluoro group such as titanium tetrafluoride (TiF₄) gas, may be used as a first source gas. A source gas containing Ti and an amino group, such as tetrakis(ethylmethylamino)titanium (Ti[N(C₂H₅)(CH₃)]₄, abbreviated as TEMAT) gas, tetrakis(dimethylamino)titanium (Ti[N(CH₃)₂]₄, abbreviated as TDMAT) gas, or tetrakis(diethyl amino)titanium (Ti[N(C₂H₅)₂]₄, abbreviated as TDEAT) gas, may be used as a second source. Also, a source gas containing Ti and an amino group having an empirical formula in which the number of ligands containing an amino group is less than or equal to ‘2’ and is less than or equal to the number of ligands containing a halogen group in the empirical formula of the first source gas may be used as a second source gas. Also, a source gas including a single amino group in an empirical formula is preferably used as the second source gas. In this case, process conditions may be set to be the same as those in the previous embodiments.

Also, for example, when a Zr film which is a Zr-based thin film formed of a single Zr element is formed as a metal-based thin film, a source gas containing Zr and a chloro group such as zirconium tetrachloride (ZrCl₄) gas or a source gas containing Zr and a fluoro group such as zirconium tetrafluoride (ZrF₄) gas may be used as a first source gas. A source gas containing Zr and an amino group, such as tetrakis(ethylmethylamino)zirconium (Zr[N(C₂H₅)(CH₃)]₄, abbreviated as TEMAZ) gas, tetrakis(dimethylamino)zirconium (Zr[N(CH₃)₂]₄, abbreviated as TDMAZ) gas, or tetrakis(diethylamino)zirconium (Zr[N(C₂H₅)₂]₄, abbreviated as TDEAZ) gas, may be used as a second source gas. Also, a source gas containing Zr and an amino group in which the number of ligands containing an amino group in an empirical formula is less than or equal to ‘2’ and is less than or equal to the number of ligands containing a halogen group in the empirical formula of the first source gas may be used as the second source gas. Also, a source gas having a single amino group in an empirical formula is preferably used as the second source gas. In this case, process conditions may be set to be the same as those in the previous embodiments.

Also, for example, when a Hf film which is a Hf-based thin film formed of a single Hf element is formed as a metal-based thin film, a source gas containing Hf and a chloro group such as hafnium tetrachloride (HfCl₄) gas or a source gas containing Hf and a fluoro group such as hafnium tetrafluoride (HfF₄) gas may be used as a first source gas. A source gas containing Hf and an amino group, such as tetrakis(ethylmethylamino)hafnium (Hf[N(C₂H₅)(CH₃)]₄, abbreviated as TEMAH) gas, tetrakis(dimethylamino)hafnium (Hf[N(CH₃)₂]₄, abbreviated as TDMAH) gas, or tetrakis(diethylamino)hafnium (Hf[N(C₂H₅)₂]₄, abbreviated as TDEAH) gas, may be used as a second source gas. Also, a source gas containing Hf and an amino group in which the number of ligands containing an amino group in an empirical formula is less than or equal to ‘2’ and is less than or equal to the number of ligands containing a halogen group in the empirical formula of the first source gas may be used as the second source gas. Also, a source gas having a single amino group in an empirical formula is preferably used as the second source gas. In this case, process conditions may be set to be the same as those in the previous embodiments.

Furthermore, the present invention is also applicable to a case in which, for example, a metal-based thin film containing a metal element and another element such as a titanium nitride film (TiN film) is formed. In this case, a cycle including a process of forming a first layer containing a metal element and a halogen group by supplying, for example, a source gas containing a metal element and a halogen group, such as TiCl₄ gas or TiF₄ gas, and a nitriding gas such as ammonia (NH₃) gas onto the wafer 200 and a process of forming a second layer (TiN layer) by modifying the first layer by supplying the nitriding gas is performed a predetermined number of times. In this case, process conditions may be set to be equal to those in the previous embodiments.

As described above, the present invention is applicable to not only forming a Si-based thin film but also forming a metal-based thin film. The effects according to the previous embodiments may also be derived when the present invention is applied to forming a metal-based thin film. That is, the present invention is also applicable to forming a thin film containing a specific element such as a semiconductor element or a metal element.

Also, when a semiconductor-based thin film such as a Si film is formed, the temperature of a substrate (temperature in the process container) is preferably set to be within, for example, a range of 300° C. to 800° C. to form a film. When the temperature in the process container is less than 300° C., it is difficult for a source gas to be adsorbed onto the substrate, thereby lowering a film-forming rate. When the temperature in the process container is greater than 800° C., a gas-phase reaction is dominant and film thickness uniformity is likely to be degraded. Also, when a metal-based thin film is formed, the temperature of a substrate (temperature in the process container) is preferably set to be within, for example, a range of 200° C. to 400° C. to form a film. When the temperature in the process container is less than 200° C., film quality may be degraded and resistivity may thus be likely to be degraded (to be increased). When the temperature in the process container is greater than 400° C., a source gas is likely to be decomposed in a nozzle and may thus be consumed before the source gas reaches the substrate. In the ranges of temperature described above, the substrate is likely to be heated by radiating radiant heat from a heating unit installed outside the process container onto the substrate. Thus, in particular, the present invention is effective when a semiconductor-based thin film or metal-based thin film is formed in these temperature ranges.

A plurality of process recipes (programs including process orders or conditions) are preferably individually prepared to be used to form various thin films according to the details of substrate processing (the type, composition ratio, quality, and thickness of a thin film to be formed), respectively. When substrate processing begins, an appropriate process recipe is preferably selected among the plurality of process recipes according to the details of substrate processing. In detail, the plurality of process recipes that are individually prepared according to the details of substrate processing are preferably housed (installed) in the memory device 121c included in the substrate processing apparatus beforehand via an electrical communication line or a recording medium (external memory device 123) storing the process recipes. Also, when substrate processing begins, the CPU 121a included in the substrate processing apparatus preferably appropriately selects a process recipe among the plurality of process recipes housed in the memory device 121c according to the details of substrate processing. Accordingly, various thin films of different types and having different composition ratios, qualities, and thicknesses may be formed using one substrate processing apparatus for a general purpose and with high reproducibility. Also, a load on an operator in manipulation (a load on the operator in inputting process order or conditions, etc.) may be decreased, and substrate processing can rapidly start without causing mistakes in operation.

However, the process recipes described above are not limited to those that are newly made and may be prepared, for example, by changing a process recipe installed in the substrate processing apparatus. When the installed process recipe is changed, the changed process recipe may be installed in the substrate processing apparatus via an electrical communication line or a recording medium storing the changed process recipe. Otherwise, the process recipe installed in the substrate processing apparatus may be directly changed by manipulating the I/O device 122 of the substrate processing apparatus.

Also, in the previous embodiments, a case in which F₂ gas is used as a cleaning gas has been described, but the present invention is not limited thereto. That is, as the cleaning gas, a gas containing at least one among the NF₃ gas, ClF₃ gas, and HF gas may be used, a gas containing a mixture of these gases may be used, or a gas obtained by adding at least one among hydrogen (H₂) gas, oxygen (O₂) gas, nitrogen monoxide (NO) gas, and nitrous oxide (N₂O) gas to these gases.

Also, in the previous embodiments, a case in which the heat absorbing layer 300 is formed as a buffer layer to saturate absorption of radiant heat into the outer wall of the process container has been described, but the present invention is not limited thereto. For example, as illustrated in FIGS. 1 and 2, a heat reflective layer 300a may be formed as a buffer layer on the outer wall of the process container (reaction tube 203) to saturate absorption of the radiant heat. When a metal-based thin film is formed on the wafer 200 using a metal element such as Co, W, TiN, etc., a deposited film formed on an inner wall of the reaction tube 203 acts to reflect at least a part of the primary radiant heat radiated from the heater 207, so that only at least a part of the primary radiant heat may be allowed to pass therethrough. When the thickness of the deposited film is sufficiently thin, the reflectivity (intensity of reflection) of the primary radiant heat increases and the transmittance (intensity of transmission) of the primary radiant heat decreases as the thickness of the deposited film increases. However, if the thickness of the deposited film reaches a predetermined thickness, the reflectivity of the primary radiant heat reaches an uppermost limit and thus does not increase any more (and the transmittance of the primary radiant heat reaches a lowermost limit and thus does not decrease any more) even when the thickness of the deposited film becomes greater than the predetermined thickness. In the present disclosure, this state, i.e., the state in which the ratio between the reflectivity and the transmittance of the primary radiant heat (i.e., reflectivity/transmittance) reaches a maximum level, is referred to as the state in which the reflection of the primary radiant heat is saturated. When a metal-based thin film is formed on the wafer 200, a film (i.e., the heat reflective layer 300a for saturating the reflection of the primary radiant heat) having the same optical features as (i.e., optically equivalent to) the deposited film formed on the outer wall of the reaction tube 203 and then removed by the cleaning process may be formed beforehand to maintain conditions of heating the wafers 200 to be constant before and after the cleaning process.

In the previous embodiments, cases in which a thin film is formed using a batch-type substrate processing apparatus capable of processing a plurality of substrates at once have been described above. However, the present invention is not limited thereto and is preferably applicable to a case in which a thin film is formed using a single-wafer substrate processing apparatus capable of processing one or several substrates at once. That is, the present invention is preferably applicable to a case in which a substrate processing apparatus including a process furnace configured to heat a substrate in a process container using the heating unit installed outside the process container, i.e., a hot wall type process furnace, is used. Also, the present invention is preferably applicable to a case in which a substrate processing apparatus configured to not only indirectly but also directly heat a substrate jointly using a heating unit installed in a substrate placing unit (susceptor) installed in a process container and another heating unit is used.

Also, an appropriate combination of the embodiments or modified examples described above may be used.

According to the present invention, the quality of a thin film may be improved by stabilizing conditions of heating a substrate when the thin film is formed on the substrate heated using a heating unit installed outside a process container.

### Exemplary Embodiments of the Present Invention

Exemplary embodiments of the present invention will be supplementarily described below.

(Supplementary Note 1)

According to one aspect of the present invention, there is provided a substrate processing apparatus including:

a process container in which processing to a substrate is performed;

a heating unit disposed outside the process container and configured to emit a first radiant heat so as to heat the substrate in the process container; and

a source gas supply system configured to supply a source gas into the process container,

wherein the process container includes a heat absorbing layer disposed on at least a portion of an outer wall of the process container and configured to absorb the first radiant heat and cause a saturation of an absorption of the first radiant heat.

(Supplementary Note 2)

The substrate processing apparatus of Supplementary note 1, wherein the apparatus is configured such that the substrate in the process container is heated by a second radiant heat (secondary radiant heat) emitted from the process container (at least the portion of the outer wall of the process container facing the heating unit) heated by causing the saturation of the absorption of the first radiant heat (primary radiant heat) by the heat absorbing layer.

(Supplementary Note 3)

The substrate processing apparatus of Supplementary note 1 or 2, wherein the heat absorbing layer has a thickness to cause the saturation of the absorption of the first radiant heat (a thickness whereat most of the primary radiant heat from the heating unit fails to reach the substrate and the substrate in the process container is heated mainly by the secondary radiant heat emitted from the process container and transferred through an atmosphere in the process container).

(Supplementary note 4)

The substrate processing apparatus of any one of Supplementary notes 1 to 3, wherein the heat absorbing layer includes a silicon layer, and has a thickness equal to or greater than 1 μm.

(Supplementary Note 5)

The substrate processing apparatus of any one of Supplementary notes 1 to 4, wherein the heat absorbing layer includes at least one of a polysilicon layer and an amorphous silicon layer, and has a thickness equal to or greater than 1 μm.

(Supplementary Note 6)

The substrate processing apparatus of any one of Supplementary notes 1 to 5, wherein the process container (at least a portion of the outer wall of the process container facing the heating unit) is made of a light-transmitting material capable of transmitting the first radiant heat (primary radiant heat).

(Supplementary Note 7)

The substrate processing apparatus of any one of Supplementary notes 1 to 6, further including a control unit configured to control the source gas supply system and the heating unit to perform a film-forming process of forming a thin film on the substrate by heating the substrate in the process container and supplying the source gas into the process container.

(Supplementary Note 8)

The substrate processing apparatus of Supplementary note 7, wherein the apparatus is configured such that a deposited film capable of absorbing or reflecting the first radiant heat (primary radiant heat) is formed on an inner wall of the process container by the film-forming process.

(Supplementary Note 9)

The substrate processing apparatus of Supplementary note 7 or 8, wherein the heat absorbing layer is made of a material optically equivalent to a material constituting the thin film (or a material constituting the thin film formed on the substrate).

(Supplementary Note 10)

The substrate processing apparatus of Supplementary note 7 or 8, wherein an absorption coefficient of the heat absorbing layer with respect to the first radiant heat is equal to that of a material constituting the deposited film (or a material constituting the thin film formed on the substrate) with respect to the first radiant heat.

(Supplementary Note 11)

According to another embodiment of the present invention, there is provided a substrate processing apparatus including:

a process container in which processing to a substrate is performed;

a heating unit disposed outside the process container and configured to emit a first radiant heat so as to heat the substrate in the process container; and

a source gas supply system configured to supply a source gas into the process container,

wherein the process container includes a heat reflective layer disposed on at least a portion of an outer wall of the process container and configured to reflect the first radiant heat and cause a saturation of an reflection of the first radiant heat.

(Supplementary Note 12)

The substrate processing apparatus of Supplementary note 11, wherein an absorption coefficient of the heat reflective layer with respect to the first radiant heat is equal to that of a material constituting the deposited film (or a material constituting the thin film formed on the substrate) with respect to the first radiant heat.

(Supplementary Note 13)

The substrate processing apparatus of any one of Supplementary notes 7 to 12, further including a cleaning gas supply system configured to supply a cleaning gas into the process container,

wherein the control unit is configured to control the cleaning gas supply system to perform a cleaning process of supplying the cleaning gas into the process container without the substrate accommodated in the process container after the film-forming process is performed a predetermined number of times so as to remove a deposit adhered to an inner wall of the process container in the film-forming process.

(Supplementary Note 14)

The substrate processing apparatus of Supplementary note 13, wherein the control unit is configured to control the source gas supply system and the heating unit to: perform a pre-coating process of forming a pre-coating layer having a thickness equal to or smaller than 300 Å on the inner wall of the process container after the cleaning process is performed by heating an inside of the process container and supplying the source gas into the process container without the substrate accommodated in the process container; and perform the film-forming process (allow the film-forming process to be started).

(Supplementary Note 15)

The substrate processing apparatus of Supplementary note 13, wherein the control unit is configured to control the source gas supply system and the heating unit to perform the film-forming process (to allow the film-forming process to be started) after the cleaning process is performed without performing a pre-coating process of forming a pre-coating layer on the inner wall of the process container by heating an inside of the process container and supplying the source gas into the process container without the substrate accommodated in the process container.

(Supplementary Note 16)

According to still another embodiment of the present invention, there is provided a substrate processing apparatus including:

a process container in which processing to a substrate is performed;

a heating unit disposed outside the process container and configured to emit a first radiant heat so as to heat the substrate in the process container; and

a source gas supply system configured to supply a source gas into the process container,

wherein the process container includes a heat absorbing layer disposed on at least a portion of an outer wall of the process container and made of a material optically equivalent to a material constituting a deposited film formed on an inner wall of the process container (or a material constituting a thin film formed on the substrate).

(Supplementary Note 17)

According to yet another embodiment of the present invention, there is provided a process container in which processing to a substrate is performed, the process container including a heat absorbing layer disposed on at least a portion of an outer wall thereof and configured to absorb first radiant heat and cause a saturation of an absorption of the first radiant heat,

wherein the process container is configured such that the substrate in the process container is heated by the first radiant heat emitted by an external heating unit and a source gas is supplied into the process container by a source gas supply system.

(Supplementary Note 18)

According to yet another embodiment of the present invention, there is provided a process container in which processing to a substrate is performed, the process container including a heat absorbing layer disposed on at least a portion of an outer wall thereof and made of a material optically equivalent to a material constituting a deposited film formed on an inner wall of the process container (or a material constituting a thin film formed on the substrate),

wherein the process container is configured such that the substrate in the process container is heated by the first radiant heat emitted by an external heating unit and a source gas is supplied into the process container by a source gas supply system.

(Supplementary Note 19)

According to yet another embodiment of the present invention, there is provided a method of manufacturing a semiconductor device, the method including:

(a) loading a substrate into a process container including a heat absorbing layer disposed on at least a portion of an outer wall thereof and configured to absorb radiant heat emitted by a heating unit and cause a saturation of an absorption of the radiant heat;

(b) forming a thin film on the substrate by heating the substrate by emitting the radiant heat from the heating unit to the substrate in the process container and supplying a source gas to the substrate in the process container; and

(c) unloading the substrate from the process container after the step (b) is performed.

(Supplementary Note 20)

According to yet another embodiment of the present invention, there is provided a method of manufacturing a semiconductor device, the method including:

(a) loading a substrate into a process container including a heat absorbing layer disposed on at least a portion of an outer wall thereof and made of a material optically equivalent to a material constituting a deposited film formed on an inner wall of the process container (or a material constituting a thin film formed on the substrate);

(b) forming a thin film on the substrate by heating the substrate by emitting the radiant heat from the heating unit to the substrate in the process container and supplying a source gas to the substrate in the process container; and

(c) unloading the substrate from the process container after the step (b) is performed.

(Supplementary Note 21)

According to yet another embodiment of the present invention, there is provided a program for causing a computer to perform a sequence of:

(a) loading a substrate into a process container including a heat absorbing layer disposed on at least a portion of an outer wall thereof and configured to absorb radiant heat emitted by a heating unit and cause a saturation of an absorption of the radiant heat;

(b) forming a thin film on the substrate by heating the substrate by emitting the radiant heat from the heating unit to the substrate in the process container and supplying a source gas to the substrate in the process container; and

(c) unloading the substrate from the process container after the step (b) is performed.

(Supplementary Note 22)

According to yet another embodiment of the present invention, there is provided a program for causing a computer to perform a sequence of:

(a) loading a substrate into a process container including a heat absorbing layer disposed on at least a portion of an outer wall thereof and made of a material optically equivalent to a material constituting a deposited film formed on an inner wall of the process container (or a material constituting a thin film formed on the substrate);

(b) forming a thin film on the substrate by heating the substrate by emitting the radiant heat from the heating unit to the substrate in the process container and supplying a source gas to the substrate in the process container; and

(c) unloading the substrate from the process container after the step (b) is performed.

(Supplementary Note 23)

According to yet another embodiment of the present invention, there is provided a non-transitory computer-readable recording medium storing a program for causing a computer to perform a sequence of:

(a) loading a substrate into a process container including a heat absorbing layer disposed on at least a portion of an outer wall thereof and configured to absorb radiant heat emitted by a heating unit and cause a saturation of an absorption of the radiant heat;

(b) forming a thin film on the substrate by heating the substrate by emitting the radiant heat from the heating unit to the substrate in the process container and supplying a source gas to the substrate in the process container; and

(c) unloading the substrate from the process container after the step (b) is performed.

(Supplementary Note 24)

According to yet another embodiment of the present invention, there is provided a non-transitory computer-readable recording medium storing a program for causing a computer to perform a sequence of:

(a) loading a substrate into a process container including a heat absorbing layer disposed on at least a portion of an outer wall thereof and made of a material optically equivalent to a material constituting a deposited film formed on an inner wall of the process container (or a material constituting a thin film formed on the substrate);

(b) forming a thin film on the substrate by heating the substrate by emitting the radiant heat from the heating unit to the substrate in the process container and supplying a source gas to the substrate in the process container; and

(c) unloading the substrate from the process container after the step (b) is performed.

What is claimed is:

1. A substrate processing apparatus comprising:
a process container in which processing to a substrate is performed;
a heating unit disposed outside the process container and configured to emit a first radiant heat so as to heat the substrate in the process container; and
a source gas supply system configured to supply a source gas into the process container,
wherein the process container comprises a heat absorbing layer disposed on at least a portion of an outer wall of the process container and configured to absorb the first radiant heat and cause a saturation of an absorption of the first radiant heat.

2. The substrate processing apparatus of claim 1, wherein the apparatus is configured such that the substrate in the process container is heated by a second radiant heat emitted from the process container heated by causing the saturation of the absorption of the first radiant heat by the heat absorbing layer.

3. The substrate processing apparatus of claim 1, wherein the apparatus is configured such that the substrate in the process container is heated by a second radiant heat emitted from at least the portion of the outer wall of the process container facing the heating unit heated by causing the saturation of the absorption of the first radiant heat by the heat absorbing layer.

4. The substrate processing apparatus of claim 1, wherein the heat absorbing layer has a thickness to cause the saturation of the absorption of the first radiant heat.

5. The substrate processing apparatus of claim 1, wherein the heat absorbing layer comprises a silicon layer, and has a thickness equal to or greater than 1 μm.

6. The substrate processing apparatus of claim 1, wherein the heat absorbing layer comprises at least one of a polysilicon layer and an amorphous silicon layer, and has a thickness equal to or greater than 1 μm.

7. The substrate processing apparatus of claim 1, wherein the process container is made of a light-transmitting material capable of transmitting the first radiant heat.

8. The substrate processing apparatus of claim 1, further comprising a control unit configured to control the source gas supply system and the heating unit to perform a film-forming process of forming a thin film on the substrate by heating the substrate in the process container and supplying the source gas into the process container.

9. The substrate processing apparatus of claim 8, wherein the apparatus is configured such that a deposited film capable of absorbing or reflecting the first radiant heat is formed on an inner wall of the process container by the film-forming process.

10. The substrate processing apparatus of claim 8, wherein the heat absorbing layer is made of a material optically equivalent to a material constituting the thin film.

11. The substrate processing apparatus of claim 9, wherein the heat absorbing layer is made of a material optically equivalent to a material constituting the deposited film.

12. The substrate processing apparatus of claim 8, wherein an absorption coefficient of the heat absorbing layer with respect to the first radiant heat is equal to that of a material constituting the thin film with respect to the first radiant heat.

13. The substrate processing apparatus of claim 9, wherein an absorption coefficient of the heat absorbing layer with respect to the first radiant heat is equal to that of a material constituting the deposited film with respect to the first radiant heat.

14. The substrate processing apparatus of claim 8, further comprising a cleaning gas supply system configured to supply a cleaning gas into the process container,
wherein the control unit is configured to control the cleaning gas supply system to perform a cleaning process of supplying the cleaning gas into the process container without the substrate accommodated in the process container after the film-forming process is performed a predetermined number of times so as to remove a deposit adhered to an inner wall of the process container in the film-forming process.

15. The substrate processing apparatus of claim 14, wherein the control unit is configured to control the source gas supply system and the heating unit to: perform a pre-coating process of forming a pre-coating layer having a thickness equal to or smaller than 300 Å on the inner wall of the process container after the cleaning process is performed by heating an inside of the process container and supplying the source gas into the process container without the substrate accommodated in the process container; and perform the film-forming process.

16. The substrate processing apparatus of claim 14, wherein the control unit is configured to control the source gas supply system and the heating unit to perform the film-forming process after the cleaning process is performed without performing a pre-coating process of forming a pre-coating layer on the inner wall of the process container by heating an inside of the process container and supplying the source gas into the process container without the substrate accommodated in the process container.

17. A process container in which processing to a substrate is performed, the process container comprising a heat absorbing layer disposed on at least a portion of an outer wall thereof and configured to absorb radiant heat and cause a saturation of an absorption of the radiant heat,
wherein the process container is configured such that the substrate in the process container is heated by the radiant heat emitted by an external heating unit and a source gas is supplied into the process container by a source gas supply system.

18. A method of manufacturing a semiconductor device, comprising:
(a) loading a substrate into a process container comprising a heat absorbing layer disposed on at least a portion of an outer wall thereof and configured to absorb radiant heat emitted by a heating unit and cause a saturation of an absorption of the radiant heat;
(b) forming a thin film on the substrate by heating the substrate by emitting the radiant heat from the heating unit to the substrate in the process container and supplying a source gas to the substrate in the process container; and
(c) unloading the substrate from the process container after the step (b) is performed.
